(19) United States
(12) Patent Application Publication
(10) Pub. No.: US 2022/0292091 A1
(43) Pub. Date: Sep. 15, 2022

(54) METHOD, APPARATUS, AND SYSTEM FOR COMPRESSION OF SPARSE DATA FOR MACHINE LEARNING TASKS

(71) Applicant: HERE Global B.V., Eindhoven (NL)

(72) Inventors: Catalin CAPOTA, Palatine, IL (US); David JONIETZ, Zurich (CH); Ali SOLEYMANI, Zurich (CH); Bo XU, Lisle, IL (US); Moritz NEUN, Zurich (CH)

(21) Appl. No.: 17/197,974

(22) Filed: Mar. 10, 2021

(51) Int. Cl. G06F 16/2458; G06F 16/29

(52) U.S. Cl. CPC G06F 16/2458; G06F 16/29; G06N 20/00

(57) ABSTRACT

An approach is provided for compression of sparse data for machine learning or equivalent tasks. The approach involves, for instance, receiving data that is binned into a plurality of bins. The data, for instance, represents a spatial surface such as a geographic region. The approach also involves processing the data by applying a compression criterion to classify one or more bins of the plurality of bins as either data-containing bins or empty bins. The approach further involves establishing a space filling curve over the plurality of bins, wherein the space filling curve linearizes the plurality of bins according to a placement order. The approach further involves storing the data-containing bins of the plurality of bins in a compressed data structure based on the placement order of the space filling curve.

### BACKGROUND

Mapping and navigation service providers are increasingly using machine learning models to make inferences based on geographic information. For many machine learning applications, geographic information is preprocessed into image-like input data (e.g., where pixels in the image-like input data represent different bins of data corresponding to a geographic region or spatial surface of interest). However, such input data often are sparse and contain many empty pixels or bins of data. As a result, service providers face significant technical challenges with respect to reducing the size of the input data and the corresponding processing time a machine learning model uses to perform inference.

### SOME EXAMPLE EMBODIMENTS

Therefore, there is a need for compressing sparse data (e.g., geographic and/or other related spatial data) to use in machine learning and/or equivalent processes.

According to one embodiment, a method comprises receiving data that is binned into a plurality of bins (e.g., image-like data comprising a plurality of pixels, or other sparse matrix data). By way of example, the data represents a spatial surface. The method also comprises processing the data by applying a compression criterion to classify one or more bins of the plurality of bins as either data-containing bins or empty bins. The method further comprises establishing a space filling curve over the plurality of bins. The space filling curve linearizes the plurality of bins according to a placement order. The method further comprises storing the data-containing bins of the plurality of bins in a compressed data structure based on the placement order of the space filling curve. The method further comprises providing the compressed data structure as an output.

According to another embodiment, an apparatus comprises at least one processor, and at least one memory including computer program code for one or more computer programs, the at least one memory and the computer program code configured to, with the at least one processor, cause, at least in part, the apparatus to receive data that is binned into a plurality of bins. By way of example, the data represents a spatial surface. The apparatus is also caused to process the data by applying a compression criterion to classify one or more bins of the plurality of bins as either data-containing bins or empty bins. The apparatus is further caused to establish a space filling curve over the plurality of bins. The space filling curve linearizes the plurality of bins according to a placement order. The apparatus is further caused to store the data-containing bins of the plurality of bins in a compressed data structure based on the placement order of the space filling curve. The apparatus is further caused to provide the compressed data structure as an output.

According to another embodiment, a non-transitory computer-readable storage medium carries one or more sequences of one or more instructions which, when executed by one or more processors, cause, at least in part, an apparatus to receive data that is binned into a plurality of bins. By way of example, the data represents a spatial surface. The apparatus is also caused to process the data by applying a compression criterion to classify one or more bins of the plurality of bins as either data-containing bins or empty bins. The apparatus is further caused to establish a space filling curve over the plurality of bins. The space filling curve linearizes the plurality of bins according to a placement order. The apparatus is further caused to store the data-containing bins of the plurality of bins in a compressed data structure based on the placement order of the space filling curve. The apparatus is further caused to provide the compressed data structure as an output.

According to another embodiment, an apparatus comprises means for receiving data that is binned into a plurality of bins. By way of example, the data represents a spatial surface. The apparatus also comprises means for processing the data by applying a compression criterion to classify one or more bins of the plurality of bins as either data-containing bins or empty bins. The apparatus further comprises means for establishing a space filling curve over the plurality of bins. The space filling curve linearizes the plurality of bins according to a placement order. The apparatus further comprises means for storing the data-containing bins of the plurality of bins in a compressed data structure based on the placement order of the space filling curve. The apparatus further comprises means for providing the compressed data structure as an output.

According to one embodiment, a method comprises receiving a compressed data structure representing binned data (e.g., image-like data comprising a plurality of pixels, or other sparse matrix data). The binned data has been processed by applying a compression criterion to classify the plurality of bins of the binned data as either data-containing bins or empty bins. The compressed data structure stores the data-containing bins linearized according to a placement order of a space-filling curve. The method also comprises extracting spatial relationship data of the binned data based on the placement order of the data-containing bins determined from the space filling curve. The method further comprises providing the spatial relationship data as an output.

According to another embodiment, an apparatus comprises at least one processor, and at least one memory including computer program code for one or more computer programs, the at least one memory and the computer program code configured to, with the at least one processor, cause, at least in part, the apparatus to receive a compressed data structure representing binned data (e.g., image-like data comprising a plurality of pixels, or other sparse matrix data). The binned data has been processed by applying a compression criterion to classify the plurality of bins of the binned data as either data-containing bins or empty bins. The compressed data structure stores the data-containing bins linearized according to a placement order of a space-filling curve. The apparatus is also caused to extract spatial relationship data of the binned data based on the placement order of the data-containing bins determined from the space filling curve. The apparatus is further caused to provide the spatial relationship data as an output.

According to another embodiment, a non-transitory computer-readable storage medium carries one or more sequences of one or more instructions which, when executed by one or more processors, cause, at least in part, an apparatus to receive a compressed data structure representing binned data (e.g., image-like data comprising a plurality of pixels, or other sparse matrix data). The binned data has been processed by applying a compression criterion to classify the plurality of bins of the binned data as either data-containing bins or empty bins. The compressed data structure stores the data-containing bins linearized according to a placement order of a space-filling curve. The apparatus is also caused to extract spatial relationship data of the binned data based on the placement order of the data-containing bins determined from the space filling curve. The apparatus is further caused to provide the spatial relationship data as an output.

According to another embodiment, an apparatus comprises means for receiving a compressed data structure representing binned data (e.g., image-like data comprising a plurality of pixels, or other sparse matrix data). The binned data has been processed by applying a compression criterion to classify the plurality of bins of the binned data as either data-containing bins or empty bins. The compressed data structure stores the data-containing bins linearized according to a placement order of a space-filling curve. The apparatus also comprises means for extracting spatial relationship data of the binned data based on the placement order of the data-containing bins determined from the space filling curve. The apparatus further comprises means for providing the spatial relationship data as an output.

In addition, for various example embodiments of the invention, the following is applicable: a method comprising facilitating a processing of and/or processing (1) data and/or (2) information and/or (3) at least one signal, the (1) data and/or (2) information and/or (3) at least one signal based, at least in part, on (or derived at least in part from) any one or any combination of methods (or processes) disclosed in this application as relevant to any embodiment of the invention.

For various example embodiments of the invention, the following is also applicable: a method comprising facilitating access to at least one interface configured to allow access to at least one service, at least one service configured to perform any one method/process or any combination of network or service provider methods (or processes) disclosed in this application.

For various example embodiments of the invention, the following is also applicable: a method comprising facilitating creating and/or facilitating modifying (1) at least one device user interface element and/or (2) at least one device user interface functionality, the (1) at least one device user interface element and/or (2) at least one device user interface functionality based, at least in part, on data and/or information resulting from one or any combination of methods or processes disclosed in this application as relevant to any embodiment of the invention, and/or at least one signal resulting from one or any combination of methods (or processes) disclosed in this application as relevant to any embodiment of the invention.

For various example embodiments of the invention, the following is also applicable: a method comprising creating and/or modifying (1) at least one device user interface element and/or (2) at least one device user interface functionality, the (1) at least one device user interface element and/or (2) at least one device user interface functionality based at least in part on data and/or information resulting from one or any combination of methods (or processes) disclosed in this application as relevant to any embodiment of the invention, and/or at least one signal resulting from one or any combination of methods (or processes) disclosed in this application as relevant to any embodiment of the invention.

In various example embodiments, the methods (or processes) can be accomplished on the service provider side or on the mobile device side or in any shared way between service provider and mobile device with actions being performed on both sides.

For various example embodiments, the following is applicable: An apparatus comprising means for performing a method of the claims.

Still other aspects, features, and advantages of the invention are readily apparent from the following detailed description, simply by illustrating a number of particular embodiments and implementations, including the best mode contemplated for carrying out the invention. The invention is also capable of other and different embodiments, and its several details can be modified in various obvious respects, all without departing from the spirit and scope of the invention. Accordingly, the drawings and description are to be regarded as illustrative in nature, and not as restrictive.

### BRIEF DESCRIPTION OF THE DRAWINGS

The embodiments of the invention are illustrated by way of example, and not by way of limitation, in the figures of the accompanying drawings:

FIG. 1 is a diagram of a system capable of compressing sparse data for machine learning or equivalent applications, according to one embodiment;

FIG. 2 is a diagram illustrating an example of sparse geographic information, according to one embodiment;

FIG. 3 is a diagram of components of a mapping platform capable of compressing sparse data, according to one embodiment;

FIG. 4 is a flowchart of a process for compressing sparse data for machine learning or equivalent applications, according to one embodiment;

FIGS. 5A and 5B are diagrams illustrating examples of sparse data with a single data layer and with multiple data layers respectively, according to one embodiment;

FIGS. 6A-6D is a diagram illustrating an example space filling curve established over sparse data, according to one embodiment;

FIG. 7 is a diagram illustrating an example quad-tree representation of the sparse data with established space filling curve, according to one embodiment;

FIGS. 8A-8C are diagrams illustrating examples of compressed data structures for representing sparse data, according to various embodiments;

FIG. 9 is a flowchart of a process for extracting spatial data from compressed data structures comprising sparse data, according to one embodiment;

FIG. 10 is a diagram illustrating an example of extracting spatial data from a compressed data structure using machine learning, according to one embodiment;

FIG. 11 illustrates an example of reconstructing data from compressed data, according to one embodiment;

FIG. 12 is a diagram of a geographic database, according to one embodiment;

FIG. 13 is a diagram of hardware that can be used to implement an embodiment of the processes described herein;

FIG. 14 is a diagram of a chip set that can be used to implement an embodiment of the processes described herein; and

FIG. 15 is a diagram of a terminal that can be used to implement an embodiment of the processes described herein.

### DESCRIPTION OF SOME EMBODIMENTS

Examples of a method, apparatus, and computer program for combining different location data sources and discovering new relationships in the data are disclosed. In the following description, for the purposes of explanation, numerous specific details are set forth in order to provide a thorough understanding of the embodiments of the invention. It is apparent, however, to one skilled in the art that the embodiments of the invention may be practiced without these specific details or with an equivalent arrangement. In other instances, well-known structures and devices are shown in block diagram form in order to avoid unnecessarily obscuring the embodiments of the invention.

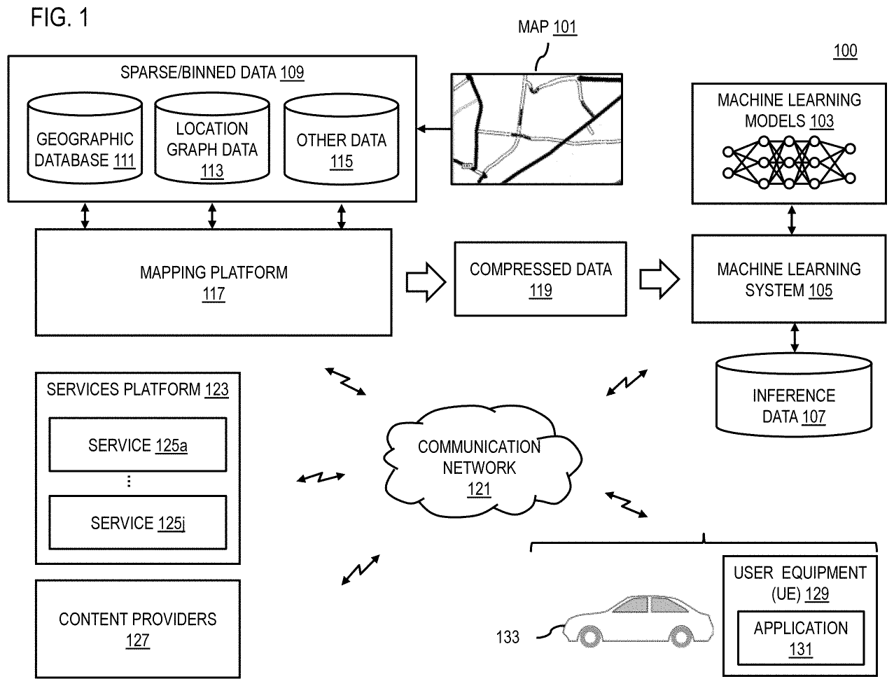

FIG. 1 is a diagram of a system 100 capable of compressing sparse data for machine learning or equivalent applications, according to one embodiment. Thematic maps (and similar cartographic representations such as map 101) typically focus on a selected aspect of geographic space, such as the road network (e.g., as shown in map 101), weather phenomena, urban areas, etc., while “zeroing out” locations where this aspect does not exist. For example, map 101 represents a road network in a geographic region of interest by showing line representations of road while other areas that do not contain road are left blank as indicated by white space (i.e., “zeroed out”). For machine learning (ML) applications, in principle, such maps can be handled just as any other image and used as input to corresponding ML models (e.g., ML models 103 of an ML system 105). In one embodiment, by inputting map or other geographic/spatial data as image like data, the system 100 advantageously leverages ML models 103 and ML techniques that have been developed for image processing for making other types of inferences (e.g., for generating inference data 107). By way of example the inferences or inference data 107 can be used for applications or functions such as, but not limited to, for classifying or predicting processes such as urban growth or traffic. However, due to their thematic focus described above, these map images (e.g., map 101) would typically be sparse, meaning that most of the pixels will be “empty.” As used, herein, the term “empty” refers to pixels or other data bins that do not carry informational value for a given ML task or application.

At the same time, however, the spatial structure of the underlying map, e.g., the locality and spatial relationship of pixels is an important feature for ML models 105 to utilize for spatial pattern extraction. Thus, simply removing said empty pixels would not be a feasible option, since this would break the spatial structure, e.g., by moving remaining pixels “far apart” which are in reality closer together, or the other way around=, and in general altering the relative and absolute locations of pixels. Such spatial characteristics, however, describe patterns which need to be preserved for many ML tasks.

On this basis, the various embodiments of the system 100 described herein solve the technical problem of encoding a large sparse spatial area into a dense structure while preserving spatial structure as much as possible. Spatial structure is the key technical challenge that is addressed by the various embodiments described herein, and the system 100 introduces a capability to maintain the locality and spatial relationship between data points and remove empty space or data (e.g., regions that contain no informational value for the ML task).

In various example embodiment, the system 100 encodes the data points in the original pixels or spatial bins (locality-preserving) of sparse or binned data 109, without modification to the underlying values (value-preserving) while maintaining the adjacency of neighboring data points to the greatest extent possible (spatial relationship preserving). Furthermore, the various embodiments of the system 100 effectively remove empty space within a spatial region and retains only coordinates of value. As used herein, the term “binned data” refers to data that is grouped into one or more bins. In one embodiment, a bin corresponds to a bounded area of a geographic region or spatial surface of interest. For example, binned data 109 can include, but is not limited to: (1) a geographic database 111 storing a digital map data representing a geographic region where, e.g., each bin corresponds to a map tile or sub-tile (or geocoordinate ranges); (2) location graph data 113 storing a location-based knowledge graph (KG) of location entities and their relationships such as places/points of interest (POIs) and the relationship between places/POIs where, e.g., each bin corresponds to a map tile or sub-tile (or geocoordinate ranges); and/or (3) any other data 115 that can be grouped or clustered into bins where each bin is associated with any range of clustering values. For example, an image of a geographic region or surface can be binned data 109 with each pixel corresponding to a respective bin based on the geographic area depicted by the pixel. In this way, the extend of the geographic area represented by the pixel can depend on the resolution of the image (e.g., with each pixel representing a smaller area in a higher resolution or pixel count image versus a lower resolution or pixel count image of the same geographic region or spatial surface).

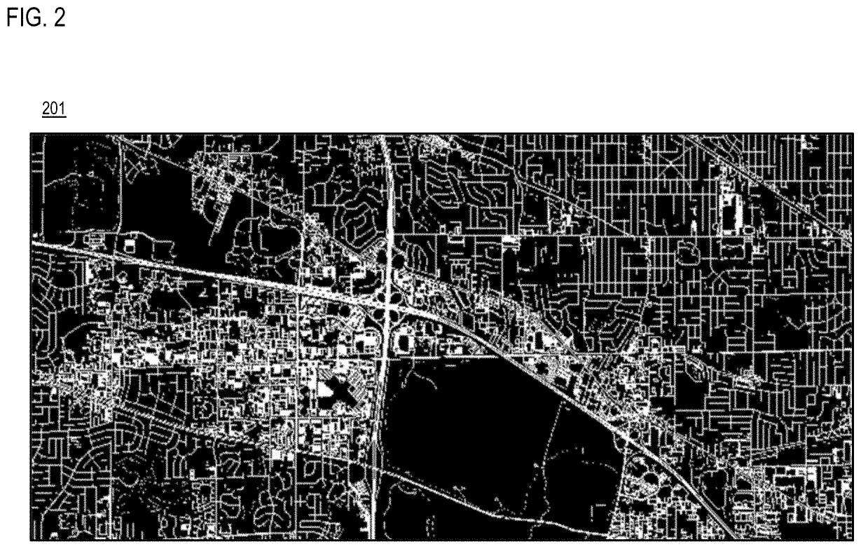

As described above, one potential problem with binned data 109 relates to the sparsity of spatial structures or data sparsity in general. FIG. 2 is a diagram illustrating an example image 201 of sparse geographic information, according to one embodiment. More specifically, the image 201 depicts a road network as example. The image 201 covers approximately a 7 mile by 3.5 mile region in a densely developed area, and each pixel in the original image (2443×1117 pixels) represents a square of 15 feet by 15 feet. If each pixel were a bin of data, 27.84% of the pixels in this image 201 would not depict a road structure. In other words, 27.84% of the pixels would be “empty” with respect to depicting a road and would thus provide limited or no informational value to tasks (e.g., ML tasks) depending on road network data.

To address this technical problem, the various embodiments of system 100 described herein introduce a programmatic way to remove these “empty” pixels/bins while maintaining the relationship between neighboring pixels for the same number of bins in the original image. By removing these empty pixels, an image with empty pixel removed of the same memory size is able to represent an increased coverage area relative to the original image containing the empty pixels. In this example, image 201 with empty pixels removed would be able to depict a geographic region that is 38.58% larger assuming new data is also encoded at the same efficiency (e.g., 0.3858=0.2784/(1−0.2784)). In less developed and sparser areas, the percentage of empty bins can increase significantly. Compressing this data enables processing of a greater land area utilizing the same memory and processing time by systems, thereby providing the technical advantages of decreasing processing latency, memory requirements, data bandwidth, etc. which can result in decreased costs.

In addition to the problem of data sparsity, the various embodiments of the system 100 described herein also provides solutions for the technical challenges associated with preserving spatial relationships and data locality when removing empty pixels or data bins. As mentioned previously, for ML tasks with geographical data, spatial relationships and locality are important features for extracting patterns and for using the extracted feature, e.g., for a prediction task. For instance, to predict the propagation of a traffic congestion through a transportation network, one would need to preserve the information about which locations are neighboring others. The general pattern that relatively near locations often show more similar behavior than more distant ones is typical for geographical phenomena and has been termed the “first law of geography.” Another example would be weather, where, e.g., moving storm fronts will affect a region first and then its neighboring areas later.

This importance of preserving neighborhood relationships is further strengthened by the fact that certain ML algorithms (e.g., convolution operations) are explicitly designed to extract local features, e.g., those which originate from neighboring pixel values. Thus, any conversion which distorts these neighborhood relationships of the original data would very likely prohibit or exacerbate the learning process of ML models that are based on convolutional operations.

Thus, when attempting to compress a geographic area or image and remove empty pixels, services providers face technical challenges to also maintaining the general locality and relative proximity of neighboring pixels. This is because compressing the image in ways that would lose the locality of data would reduce the efficiency of searching for regions of interest. At the same time, minimizing these clusters would make processing more efficient by enabling the minimum number of lookups when searching for a region or iteratively processing the data.

To address these technical challenges, the various embodiments of the system 100 described herein introduces a novel approach for preprocessing sparse and/or binned input data (e.g., image-like data or other sparse matrix input data) to ML models 103. The system 100 (e.g., via a mapping platform 117) provides the capability to efficiently encode a dataset (e.g., sparse/binned data 109 such as the geographic database 111, location graph data 113, other data 115, etc.) into compressed data 119 in a way that reduces the size and/or processing time the ML system 105 and/or ML models 103 (e.g., a neural network or equipment) uses to perform inference (e.g., generate inference data 107).

In one embodiment, the compressed data 119 and/or inference data 107 can be provided as an output over a communication network 121 to other components of the system 100 such as, but not limited to: (1) a services platform 123 comprising one or more services 125a-125j (collectively referred to as services 125) such as one or more location-based services applications that perform functions based on the compressed data 119 and/or inference data 107; and (2) content provider platforms 127 that store the compressed data 119 and/or inference data 107 (e.g., for access by other components of the system 100) or provide data (e.g., sparse/binned data 109) for generating the compressed data 119 and/or inference data 107. By way of example, the services 125 can be targeted to functions such as, but not limited to, traffic prediction and routing for deliver to end user devices such as, but not limited to, one or more user equipment (UE) devices 129, applications 131 executing on the UEs 129, vehicles 133, and/or the like. While the preprocessing/encoding methodology described works well for these use cases, it could be utilized for other sparse spatial datasets as well.

In one embodiment, the system 100 (e.g., via the mapping platform 117) takes in data 109 that is tiled or binned, e.g., data that covers a geographic region or abstract surface (e.g., spatial surface). In one embodiment, the data 109 may contain multiple layers of related attributes (e.g., Layer 1—Road Network, Layer 2—Accidents, Layer 3—Traffic, etc.). The tile extent determines the resolution of interest: if the data is tiled in very small tiles then resolution is high, if data is aggregated at higher levels then resolution is low.

In one embodiment, a compression criterion is established to determine empty/dead areas (e.g., empty pixels or bins). For example, only traffic or accidents within 30 meters of roadways may be of interest. In other words, the plurality of data layers of the data 109 can include a road network layer representing one or more roads associated with the spatial surface, a traffic data layer representing traffic associated with the spatial surface, an accident data layer representing one or more accidents associated with the spatial surface, or a combination thereof. In this case, the compression criterion classifies the one or more bins or pixel based on a distance threshold between the one or more roads and either of the traffic or the one or more accidents. This criterion should be evaluated on each bin and return a Boolean value if the given bin is of interest. If the given bin or pixel is not of interest based on the criterion (e.g., does not contain an accident within 30 meters of a road), then the bin is marked or classified as empty.

Next, a space filling curve (e.g., a Hilbert Curve or equivalent) is established over the given bins to linearize the coordinates and order points in minimum geolocated clusters. The points along this curve that contain valid data bins comprise the compressed data 119 (e.g., data containing only the valid or data containing bins and not the empty bins). In one embodiment, the data points of the compressed data 119 can be placed in a tree structure (e.g., a quadtree structure) for quick indexing and lookup.

Lastly, in one embodiment, the compressed data 119 is stored in layers according to the ordering of placement of each cell within the space filling curve/quadtree indexes. The data may be rendered as a single dimensional array or converted into other dense multidimensional structures as the need arises.

The approach of the various embodiments described herein provide for several technical advantages:
Allows for rule-based definition of empty space or bins, and removal of such while preserving valid pixel or bin values.
Preserves spatial structure via Hilbert curve encoding and/or tree structure (e.g., quadtree).
Resulting dense frames (e.g., compressed data 119) can be enriched with quadtree and Hilbert cell number in separate channels to be utilized by the ML model 103.

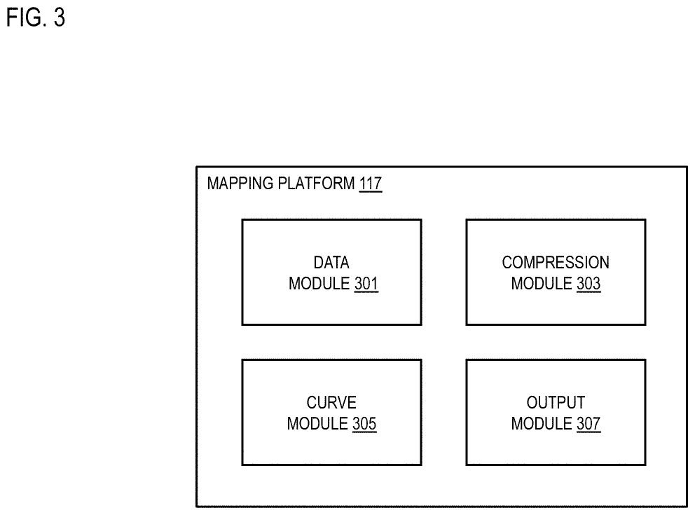

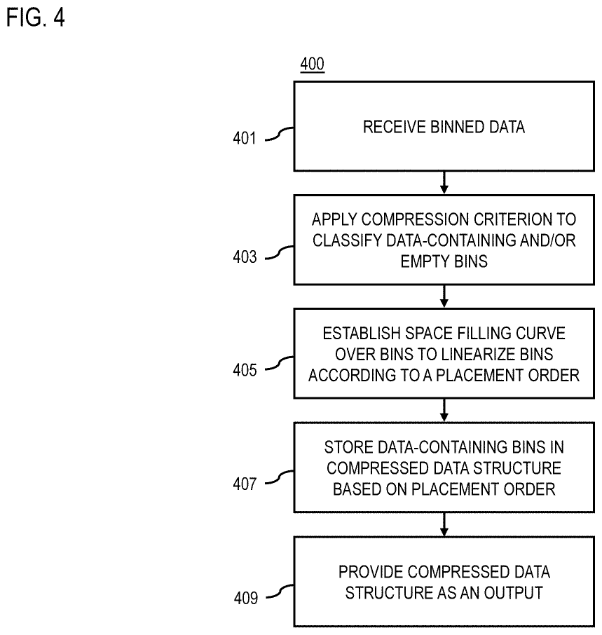

FIG. 3 is a diagram of components of a mapping platform capable of compressing sparse data, according to one embodiment. In one embodiment, as shown in FIG. 3, the mapping platform 117 of the system 100 includes one or more components for compressing sparse data for machine learning and equivalent applications according to the various embodiments described herein. It is contemplated that the functions of the components of the mapping platform 117 may be combined or performed by other components of equivalent functionality. As shown, in one embodiment, the mapping platform 117 includes a data module 301, a compression module 303, a curve module 305, and an output module 307. The above presented modules and components of the mapping platform 117 can be implemented in hardware, firmware, software, or a combination thereof. Though depicted as a separate entity in FIG. 1, it is contemplated that the mapping platform 117 may be implemented as a module of any of the components of the system 100 (e.g., a component of the machine learning system 105, services platform 123, services 125, content providers 127, UEs 129, vehicles 133, and/or the like). In another embodiment, one or more of the modules 301-307 may be implemented as a cloud-based service, local service, native application, or combination thereof. The functions of the mapping platform 117 and modules 301-307 are discussed with respect to FIGS. 4-11 below.

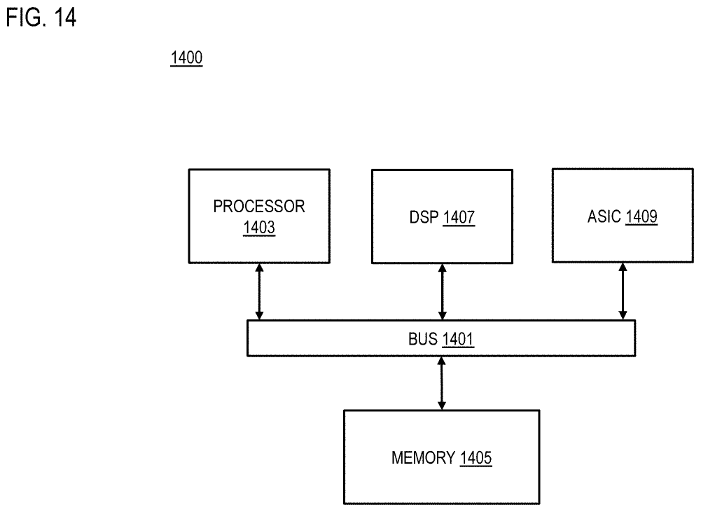

FIG. 4 is a flowchart of a process for compressing sparse data for machine learning or equivalent applications, according to one embodiment. In various embodiments, the mapping platform 117 and/or any of the modules 301-307 may perform one or more portions of the process 400 and may be implemented in, for instance, a chip set including a processor and a memory as shown in FIG. 14. As such, the mapping platform 117 and/or any of the modules 301-307 can provide means for accomplishing various parts of the process 400, as well as means for accomplishing embodiments of other processes described herein in conjunction with other components of the system 100. Although the process 400 is illustrated and described as a sequence of steps, it is contemplated that various embodiments of the process 400 may be performed in any order or combination and need not include all of the illustrated steps.

In step 401, the data module 301 receives or otherwise determines or accesses data (e.g., binned data 109) that is binned into a plurality of bins. In one embodiment, the binned data represents geographic or spatial data that correspond to geographic data (e.g., digital map data of the geographic database 111). Accordingly, the bins are geographic clusters or groupings of the geographic data. For example, the bins can correspond to map tiles or sub-tiles of the geographic data and the data in each bin is the geographic data associated with the corresponding map tile or sub-tile. In other words, in one embodiment, the binned data 109 represents a spatial surface, and the spatial surface, in turn, corresponds to a geographic region.

However, it is noted that geographically related data is provided as only one example of binned data 109 and should not be considered as a limitation. It is contemplated that the various embodiments described herein are applicable to any type of sparse data. More generally, the various example embodiments are applicable to any data that is stored in a matrix or equivalent data structure (e.g., image like data), and the plurality of bins corresponds to one or more elements of the matrix.

In one embodiment, the data 109 can be rasterized to an image or other image like data. As used herein, “image like data” refers to data can include bins that can be arranged along an x and y axis of a surface that is equivalent to a pixel arrangement of an image. The visual characteristics of each bin or pixel of the image like data can be represented or rendered based on the values of the data in each bin. Accordingly, the plurality of bins corresponds to one or more pixels of the image.

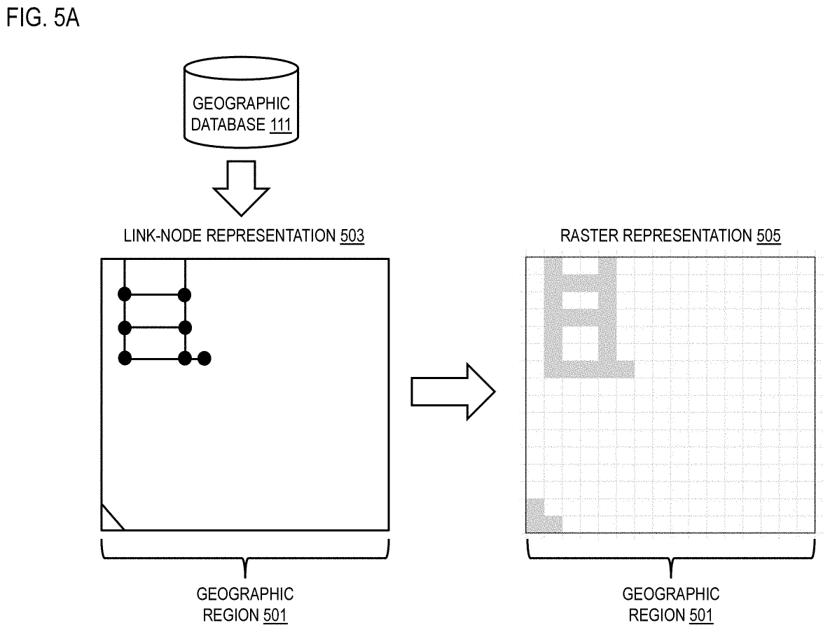

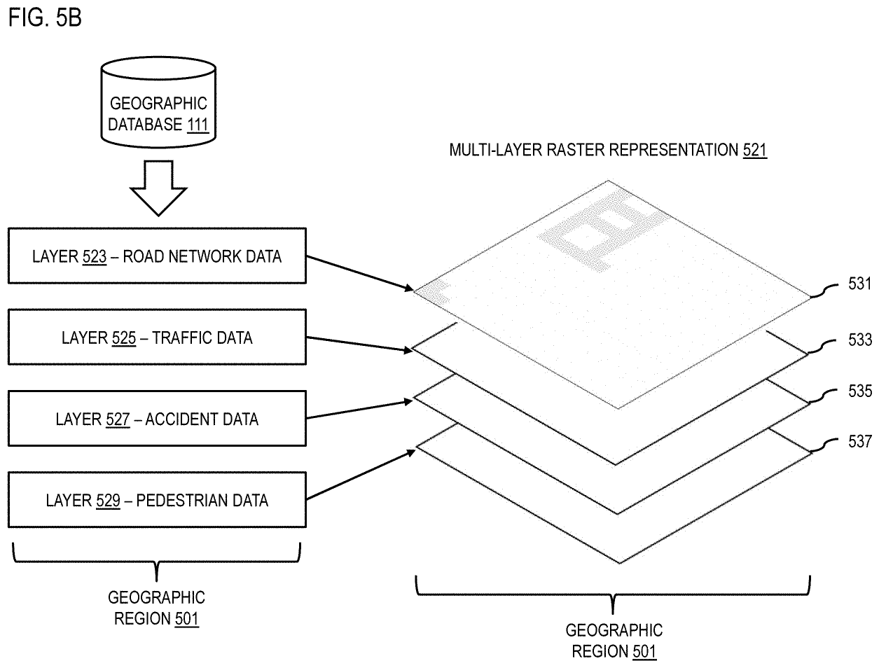

FIG. 5A is a diagram illustrating an example of sparse data, according to one embodiment. In the example of FIG. 5A, a geographic region 501 of interest is selected. The map data for the geographic region 501 can then be retrieved from the geographic database 111 or other equivalent digital map data. In this example, as shown, the geographic database 111 uses a link-node representation 503 of a road network in the geographic region 501 that represents intersections and road endpoints as nodes (e.g., indicated by a solid circle in FIG. 5A) and road links between the nodes as line segments (e.g., indicated by lines between the nodes). The one or more map tiles representing the geographic region 501 can be rasterized in a raster representation 505 (e.g., an image). The raster representation 505 can be created to be the same shape as the region of interest and the pixel resolution can be specified to depict the link-node representation at a target resolution. In this case, each pixel (e.g., represented by a respective square in the raster representation 505) represents a corresponding portion or bin of the geographic region 501.

If a link or node representing a road network appears in that portion or bin, the corresponding pixel is shaded gray to represent that portion of the road network. The resulting raster representation 505 becomes an image in which pixels depicting a road is shaded gray and pixels with no road is colored white. In this case, the raster representation 505 (e.g., an image) is sparse with a relatively few pixels shaded gray to indicate a road relative to the number of empty pixels (e.g., colored white to indicate no road). In one embodiment, one goal of the process 400 is to encode the data (e.g., road network data) within this image (e.g., raster representation 505) in the smallest possible representation, while—as stated above—maintaining as much as possible the spatial structure (e.g., neighborhood relationships between pixels, location of pixels) and removing any empty space.

In one embodiment, the image could contain multiple layers of data in addition to or in place of the road network illustrated in the example of FIG. 5A. FIG. 5B illustrates an example multi-layer raster representation 521 of the geographic region 501. In the example of FIG. 5B, the geographic database 111 stores multiple layers of data for the geographic region 501. For example, in addition to a layer 523 that stores a road network data layer representing the physical roads in the geographic region 501, there could be other layers that overlap this roadway that provide additional attributes such as, but not limited to, traffic (e.g., stored in traffic data layer 525), accidents (e.g., stored in accident data layer 527), pedestrian movement (e.g., stored in pedestrian data layer 529), etc. All layers could be rasterized and/or encoded using the same compression algorithm into a denser representation of this space (e.g., multi-layer raster representation 521) comprising, e.g., raster layer 531 representing the road network data layer 523, raster layer 533 representing traffic data layer 525, raster layer 535 representing accident data layer 527, and raster layer 537 representing pedestrian data layer 529. In other words, in one embodiment, the data 109 comprises a plurality of data layers (e.g., data layers 523-529), and wherein the plurality of multiple data layers 523-529 of the data in the data-containing bins is stored in the compressed data structure (e.g., compressed data 119) based on the placement order of the space filling curve discussed further below in step 405.

In step 403, the compression module 303 processes the data by applying a compression criterion to classify one or more bins of the plurality of bins as either data-containing bins or empty bins. In one embodiment, data-containing bins would be retained while empty bins would be removed in the compressed data 119. It is contemplated that the compression criterion can be any rule or classification system that can output a classification of either data-containing bin or empty bin given the data associated with a bin of the data. For example, in image and image-like data, a bin corresponds to one or more pixels of the image. The compression criterion would be used to determine when the data associated with the bin or pixel has informational value for a given ML task or any other application that makes use of the binned data.

In one embodiment, during encoding, a function is provided to determine cells (e.g., bins, pixels, or other data clusters) of interest. By way of example, this function or compression criterion could be as simple as a function to determine if the cell/bin contains data or more complex functions like all cells/bins within a certain distance of a data layer. An example would be raw GPS probes (probe data) on a road network. As the GPS positions within the probe data might not be exactly matching to the underlying road segment, a threshold could be established such as all or a threshold number of probes within 30 meters of the roads represented in the road layer. In this case, the compressed image or other data structure (e.g., compressed data 119) would have two layers: one layer representing the probe data, and a second layer representing the road network. The encoding would apply to both layers given a dense structure of only probes within the given distance of the roadway.

In one embodiment, the compression criterion can be applied to each data layer independently such that a bin in one data layer can be classified as empty and removed in that data layer, while the same bin in a second data layer can be classified as data-containing or valid and retained in that second data layer. In other embodiments, the multiple data layers of the same bin can be evaluated in the aggregate such that all data layers or a threshold percentage of the data layers must be classified as empty to be removed.

In step 405, the curve module 305 establishes a space filling curve over the plurality of bins. A space filling curve, for instance, is a parameterized function which maps the bins to a continuous curve that traverses the bins of the binned data 109 (e.g., pixels of an image) in an order that reflects the spatial relationship or locality of the bins. In other words, the space filling curve linearizes the plurality of bins according to a placement order defined by the properties of the space filling curve. It is contemplated that any space filling curve can be used according to the embodiments described herein. Example space filling curves that can be used include, but are not limited to, a Morton space filling curve, Koch curve, Hilbert Curve, or equivalent.

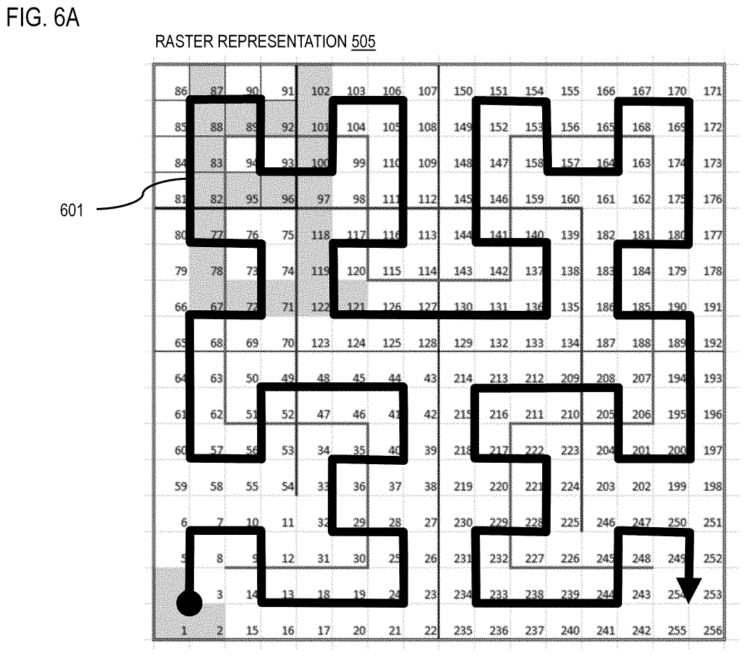

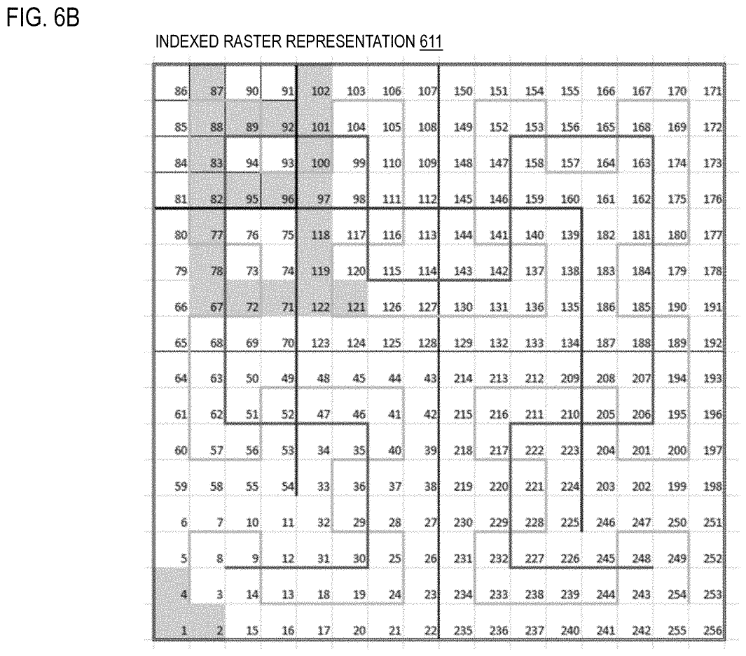

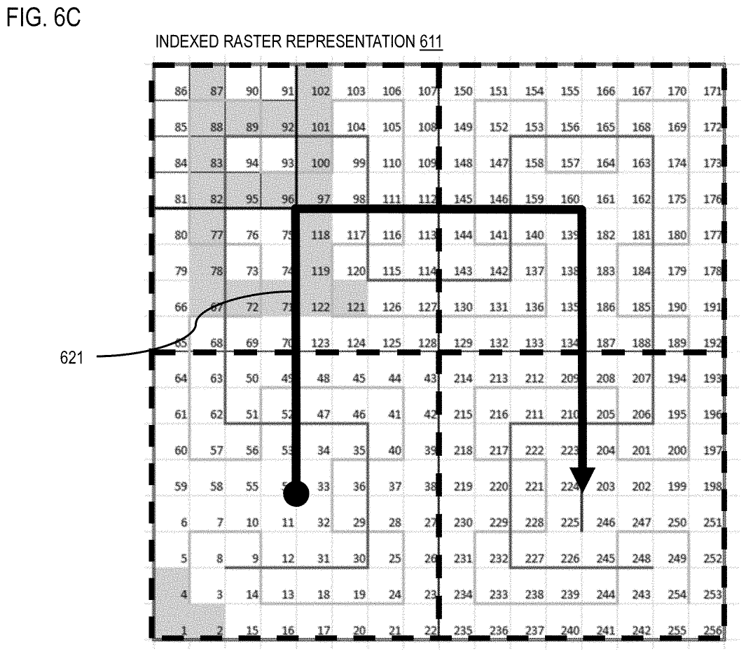

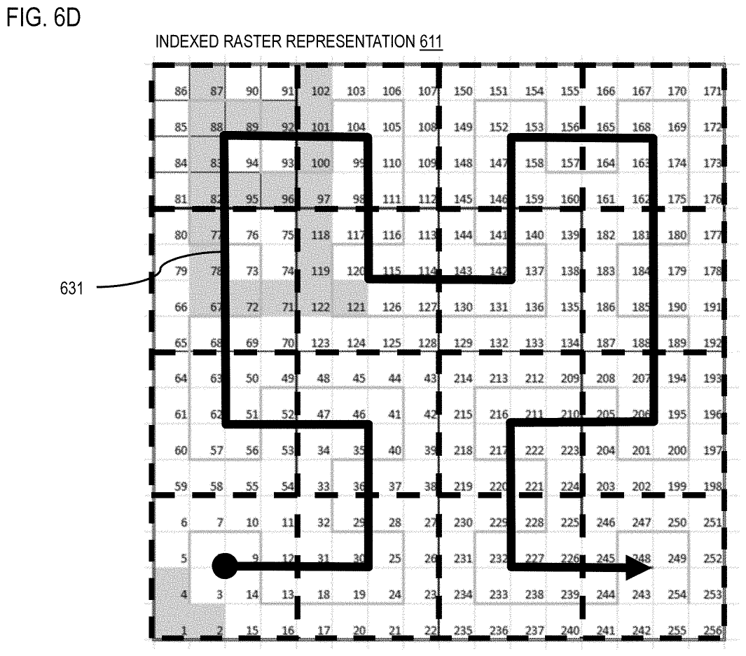

FIG. 6A is a diagram illustrating an example space filling curve established over sparse data, according to one embodiment. As shown, the raster representation 505 of road network data is the sparse data over which the space filling curve 601 is established. In this example, a Hilbert curve is used as the space filling curve to span the extent of the raster representation 505. The Hilbert curve, for instance, is assumed to maintain the closest relationships between neighboring points within the minimum number of clusters (e.g., during a search). The curve module 305, for instance, determines the parameters for generating the Hilbert curve based on the dimensions of the raster representation 505 so that each pixel or bin of the raster representation 505 can be indexed according to a placement order. The placement order, for instance, can be based on the starting point of the Hilbert curve 601 (e.g., indicated by a dot at the beginning of the curve 601) up to the end point of the curve 601 (e.g., indicated by an arrow at the end of the curve 601). The bins or pixels adjacent to the curve 601 can then be indexed or numbered sequentially as shown in FIG. 6B in which the curve 601 has been removed to show the indexing of pixels 1 to 256 (e.g., based on a 16×16 pixel size of the indexed raster representation 611. Because of the nature of the Hilbert curve 601 (and also other equivalent space filling curves) pixels with closer index numbers are also spatially closer together. Thus, even when the pixels are linearized according to their index numbers, the spatial relationships information remain encoded in the index numbers.

In one embodiment, the image or image like data need not be a geospatial region, the encoding of the process 400 is also applicable to abstract canvases of differing sizes and shapes. For the images that are not geospatial in nature, the extent and proportions of the original image can be used to allocate the curve and be able to reconstruct the original image if need be.

In one embodiment, for geospatial regions, the space filling curve coordinates (e.g., Hilbert curve coordinates) could be utilized to convert to and from other coordinate systems such as latitude/longitude enabling spatial lookup functions such as intersections of shapes or distances. This conversion can be performed by knowing the geocoordinates of the boundaries of the geographic region represented by the raster representation 505 and then computing the corresponding coordinates of each bin or pixel (e.g., the boundaries of each bin or pixel) based on the known geocoordinates of the overall boundary of the geographic region of interest. In other words, in one embodiment, the plurality of bins is respectively associated with coordinate data of a coordinate system (e.g., latitude/longitude). The space filling curve can be used to convert the coordinate data to and from the coordinate system and the placement order of the space filing curve. In this way, the geocoordinates of the original data can be maintained to enable the curve module 305 to perform geometric calculations on the data contained in the image or binned data. Examples of such geometric calculations include, but are not limited to, finding all data points within a bounding box, or calculating the distance between two pixels or roadways (or other features) represented in the data.

In one embodiment, the space filling curve can be defined at different resolution or curve levels so that instead of indexing only at the highest resolution of individual bins or pixels of the raster representation 505, the curve module 305 can index based on higher order groupings of pixels. For example, when using a tree structure (e.g., a quadtree) to represent the binned data 109, the space filling curve comprises one or more curve levels respectively corresponding to one or more tree levels of the tree structure.

FIGS. 6C and 6D in combination with FIGS. 6A and 6B illustrate establishing a space filling curve at multiple curve levels, according to one embodiment. For example, a Hilbert curve (or other space filling) is created to span the extent of the image at multiple curve levels. As indicated above, the raster representation 505 has a size of 16×16 pixels. At this example size, a 5-layer curve is sufficient to capture on the per pixel level the data contained in the bins or pixels of the raster representation 505. In other words, a 5-layer Hilbert curve established over the raster representation 505 would be able to uniquely index each pixel of the raster representation 505. For example, a level 1 curve represents the indexed raster representation 611 as a single unit or bin. FIG. 6C illustrates a Hilbert curve 621 at level 2 which spans the indexed raster representation 611 over four 8×8 pixel bins. FIG. 6D illustrates a Hilbert curve 631 at level 3 which spans the indexed raster representation 611 over 16 4×4 pixel bins. FIG. 6A illustrates a Hilbert curve 601 at level 4 which spans the raster representation 505 at a per pixel level (e.g., spans all 256 pixels). Finally, level 5 represents the number cells or bins of the indexed raster representation 611 as shown in FIG. 6B.

In step 407, the compression module 303 stores the data-containing bins of the plurality of bins in a compressed data structure (e.g., compressed data 119) based on the placement order of the space filling curve. In other words, the compressed data structure will contain only the data-containing bins while removing the empty bins to advantageously reduce the size of the compressed data structure and the corresponding computing resources required to store and process the compressed data 119. The spatial relationship and locality are maintained based on the placement order (e.g., index number) of the space filing curve used to linearize the data.

In one embodiment, the compressed data structure is indexed based on a tree structure comprising one or more spatial clusters of the plurality of bins. The encoding, for instance, creates a compressed quad tree (e.g., compressed data 119) with the remaining data point coordinates (e.g., data associated with the data-containing bins and not the empty bins) within the Hilbert Curve or equivalent space filling curve.

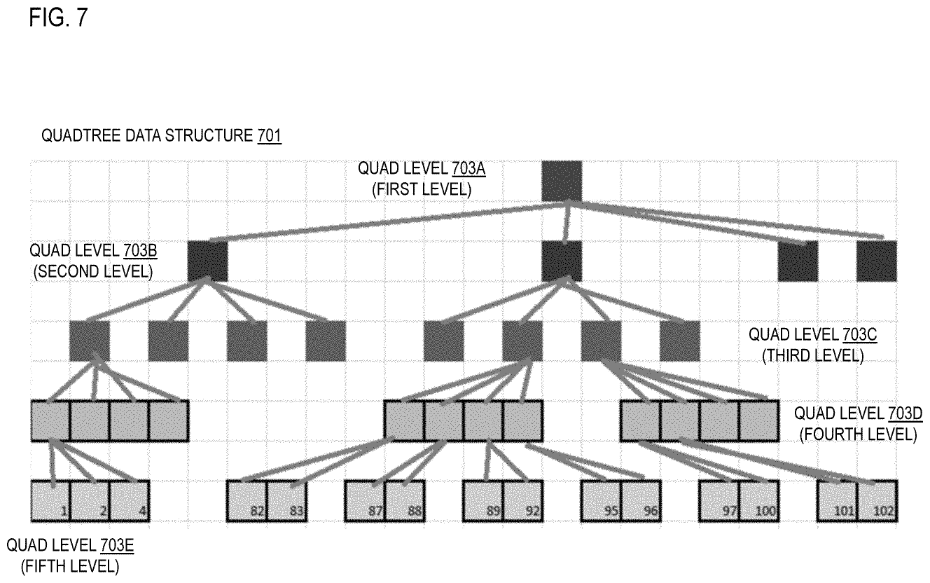

FIG. 7 illustrates an example of how this tree encoding would look for the raster representation 505 of FIG. 5A, according to one embodiment. In the example of FIG. 7, the tree structure is more specifically a quadtree. The quadtree, for instance, provides an efficient search of coordinate space, it can also be efficiently stored as a single dimensional array. However, it is noted that the quadtree is provided by way of illustration and not as a limitation, and it is contemplated that any other tree structure or equivalent data structure can be used according to the embodiments described herein. A quadtree, for instance, is a tree data structure where each internal node has exactly four children.

As shown, in FIG. 7, the quadtree data structure 701 at its first level (quad level 703a) corresponds to the entire indexed raster representation 611 as shown in FIG. 6B which is at a Hilbert curve level 1. The second level (quad level 703b) corresponds to the four 8×8 pixel bins traversed by the Hilbert curve 621 of FIG. 6C. The third level (quad level 703c) corresponds to the 16 4×4 pixel bins traversed by the Hilbert curve 631 of FIG. 6D matched respectively to the four 8×8 pixel bins of the second level (quad level 703b). The fourth level (quad level 703d) corresponds to the 256 individual bins traversed by the Hilbert curve 601 of FIG. 6A matched respectively to the 16 4×4 bins of third level (quad level 703c). Finally, the fifth level (quad level 703e) corresponds to the data-containing bins remaining after removal of bins that have been classified as empty according to the applied compression criterion.

In one embodiment, the compression module 303 stores the remaining data bins of the fifth level of the quadtree as the compressed data 119 (e.g., compressed data structure). In one embodiment, the compressed data comprises a header and one or more data frames in which the header stores one or more characteristics of the space filling curve, the tree structure, or a combination thereof; and in which the one or more data frames store the data associated with the data-containing bins.

In other words, the space filling curve characteristics (e.g., Hilbert or other curve characteristics such as type of curve, parameters generating the curve, curve level, etc.) and quad tree of active cells (e.g., data-containing bins not removed by the compression algorithm) are stored as a header. The remaining data is then organized into layers comprised of multiple frames. More specifically, in one example embodiment, the output format is as follows:
1. Header containing the quadtree of active bins (providing their offset into storage array), boundary of the region of interest (in geospatial coordinates or other format for abstract regions), metadata about the frames (e.g., for movies or other time-stamped data, could be the timestamp between frames, or other attributes that pertain to all layers).
2. Data—One to Many layers of data, each layer being comprised of a header describing the layer and one to many frames of data. For each active or data-containing bin (e.g., as classified by the compression algorithm), the quadtree can also be provided as an additional channel or layer to allow a convolutional operation to make use of that additional information for pattern extraction.

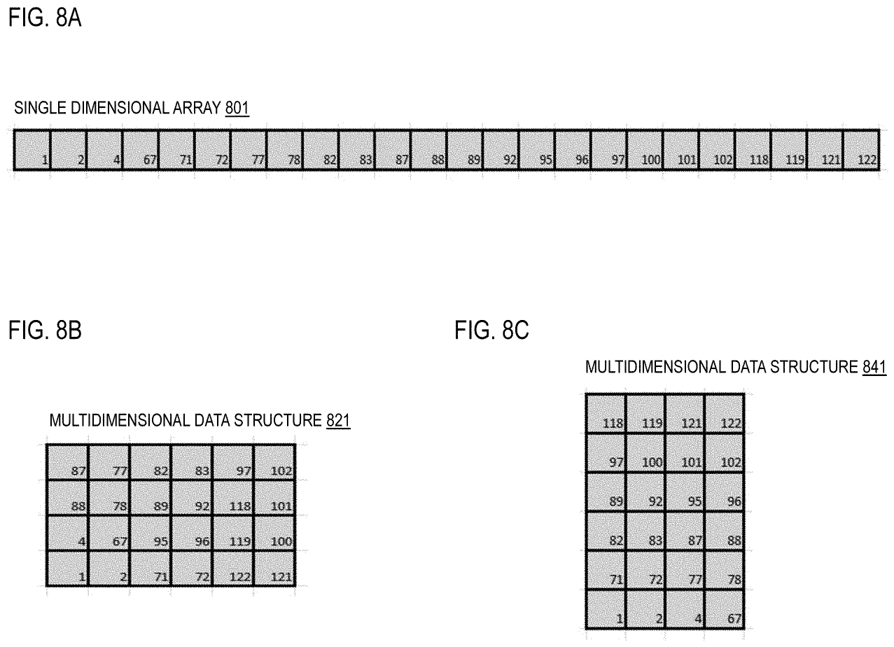

The frames, for instance, are stored as single dimensional arrays and can be visualized as such, an example for the road network associated with the raster representation 505 of FIG. 5A is shown in FIG. 8A. In the example of FIG. 8A, the compressed data structure (e.g., the compressed data 119 resulting from the compression of raster representation 505 according to the embodiments described herein) is a single dimensional array 801. The single dimensional array 801 compressed a linearized sequence of the data containing bins (e.g., non-empty bins or pixels) of the original binned data (e.g., raster representation 505) indexed based on the placement order indicated by the established space filling curve (e.g., Hilbert curve). In the illustrated example, each box represents a data-containing or valid bin and the number in each box represents an index value provided by the space filling curve. Because of the nature of the space filling curve, the indexed values help to maintain the spatial relationship and locality of the data because bins that are closer in index value are also closer in space (e.g., geographical space).

In addition or alternatively, the compressed data structure can be a dense multidimensional data structure. FIGS. 8B and 8C illustrate respective example dense multidimensional data structures 821 and 841 that present the compressed data in non-linear data structures. Other renderings are possible that still retain spatial proximity, including aggregations of Hilbert curves at different levels representing datapoints. Some examples are shown alongside this text. The cell numbers resulting from the Hilbert curve space filling could be provided for each cell as an additional value to allow the convolutional operations to utilize it for pattern extraction.

In step 409, the output module 307 provides the compressed data structure (e.g., compressed data 119) as an output. For example, the compressed data 119 can be provided to any of the components of the system 100 including but not limited to the ML system 105, ML model 103, services platform 123, services 125, content providers 127, vehicles 133, UEs 129, and/or the like.

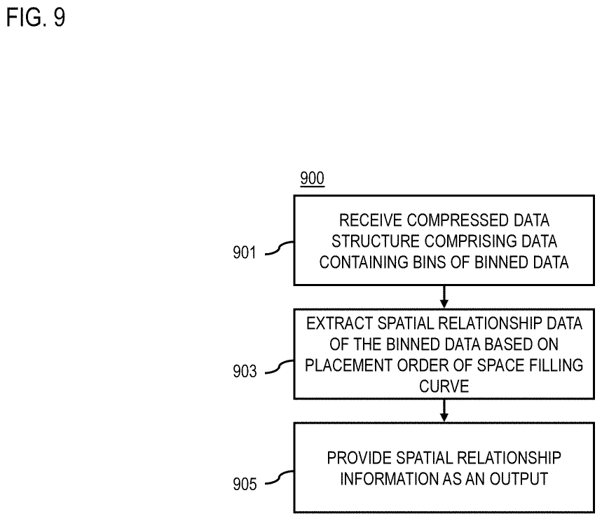

FIG. 9 is a flowchart of a process 900 for extracting spatial data from compressed data structures comprising sparse data, according to one embodiment. In various embodiments, the mapping platform 117 and/or any of the modules 301-307 may perform one or more portions of the process 900 and may be implemented in, for instance, a chip set including a processor and a memory as shown in FIG. 14. As such, the mapping platform 117 and/or any of the modules 301-307 can provide means for accomplishing various parts of the process 900, as well as means for accomplishing embodiments of other processes described herein in conjunction with other components of the system 100. Although the process 900 is illustrated and described as a sequence of steps, it is contemplated that various embodiments of the process 900 may be performed in any order or combination and need not include all of the illustrated steps.

In step 901, the compression module 303 receives a compressed data structure (e.g., compressed data 119) representing binned data. In one embodiment, the compressed data 119 is generated according to the embodiments described above with respect to process 400 of FIG. 4. For example, the binned data has been processed by applying a compression criterion to classify the plurality of bins of the binned data as either data-containing bins or empty bins. The compressed data structure then stores the data-containing bins linearized according to a placement order of a space-filling curve. In one embodiment, the compressed data structure is indexed based on a tree structure comprising one or more spatial clusters of the plurality of bins.

Furthermore, in one embodiment, the compressed data 119 comprises a header and one or more data frames with the header storing one or more characteristics of the space filling curve, the tree structure, or a combination thereof; and the one or more data frames storing the data associated with the data-containing bins.

In step 903, the compression module 303 extracts spatial relationship data of the binned data based on the placement order of the data-containing bins determined from the space filling curve. In one embodiment, the spatial relationship data is extracted by providing the output as an input into a machine learning model 103 (e.g., a neural network) of the machine learning system 105.

In one embodiment, the ML models 103 of the ML system 105 include 2D-Convolutional operations which are state-of-the-art algorithms for image (and map-like) data. Other than fully-connected layers, they typically extract features from the immediate neighboring pixels (limited perceptive field). In order to detect features which involve more distant locations, typically a stacking of multiple alternating convolutional and maxpooling layers is necessary in order to incrementally increase the perceptive field of the neural network. Given the case of sparse image data, where valid pixel locations are separated by gaps of empty pixels, large receptive fields (and therefore multiple stacked convolutional layers) would be required to bridge the gaps and extract potential patterns among these valid pixel locations. Every additional layer of a neural network increases the number of model parameters (and therefore memory requirements)—which might also increase the risk of overfitting—and computation operations.

However, by using the compression approach described herein, the system 100 can achieve similar performance with shallower neural networks because of the decreased size of the received compressed data 119. In one embodiment, the more densely encoded larger spatial areas provided according to the embodiments described herein would advantageously and effectively increase the perceptive field of individual convolutional layers and might lead to improved predictive results with less deep convolutional neural networks or other equivalent ML models 103. Thus, the various embodiments described herein enable new methods or algorithms to be used to solve problems that were previously too latent, expensive, or otherwise impractical to operate.

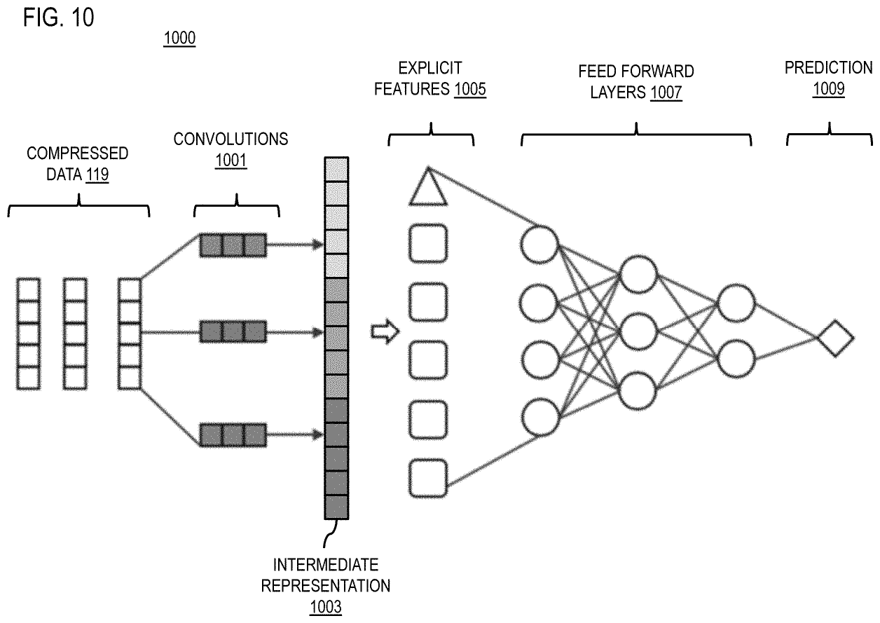

FIG. 10 is a diagram illustrating an example of extracting spatial data from a compressed data structure using machine learning, according to one embodiment. As shown in the example ML architecture 1000 of FIG. 10, the received compressed data 119 (e.g., image or image like data such as geographic/spatial data) can be fed into one or more convolutions 1001. The convolutions 1001, for instance, are used to extract or learn feature maps from the compressed data 119 to generate an intermediate representation 1003 (e.g., to increase the perceptive field as discussed above and/or for any other use). In other words, the compressed data 119 can be input into a convolutional neural network with convolutional layers corresponding to the selected convolutions 1001. The intermediate representation 1003 is learned by passing the input matrix through the convolutional layers and concatenating or otherwise aggregating (e.g., via maxpooling) the results into the intermediate representation 1003.

Additional explicit features 1005 (e.g., header information characterizing the compressed data 119, space filling curve, known spatial/semantic relationships, etc.) can be added to the intermediate representation 1003. The intermediate representation 1003 (with additional explicit features 1005) can then be passed through the feed forward layers 1007 of the machine learning architecture 1000 to compute a prediction 1009 that is based at least in part on the spatial relationship and locality data maintained in the compressed data 119 according to the approaches described herein. In one embodiment, the prediction 1009 can be any predictive task to be performed on data such as, but not limited to traffic prediction, routing, spatial recommendations, etc.

In the example embodiments above, the spatial relationship and locality information is extracted implicitly as part of the ML task. In addition or alternatively, the spatial relationship and locality information can be extracted more explicitly by reconstructing the original image or binned data 109 from the compressed data 119. This decoding process is the opposite of the encoding/compression processes described above (e.g., process 400 of FIG. 4).

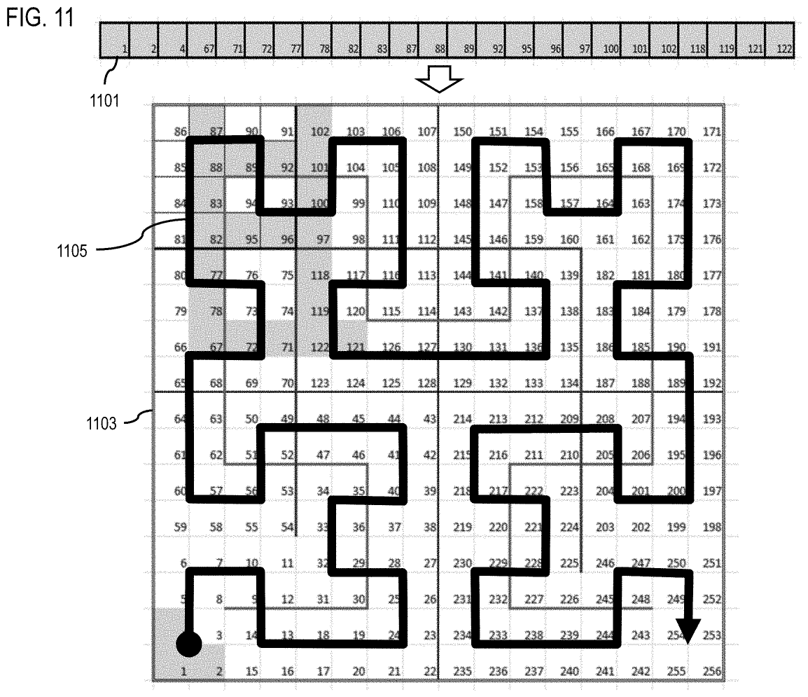

FIG. 11 illustrates an example of reconstructing data from compressed data 119, according to one embodiment. In the example of FIG. 11, the compression module 303 receives a compressed data structure 1101 generated according to the embodiments described herein. The compressed data structure 1101 is a single dimensional array comprising active or data-containing bins of a raster representation of a road network. The single dimensional array is indexed according to a space filling curve (e.g., a Hilbert curve). The compression module 303 can extract the curve parameters, image size, geographic boundary, and/or other related information from the header of the compressed data structure 1101.

Based on the header data, the compression recreates a reconstructed raster representation 1103 that matches the pixel dimensions of the original image or raster representation (e.g., a 16×16 pixel image). Based on the space filling curve (e.g., Hilbert curve) and its parameters indicated in the header data, the compression module 303 can establish the Hilbert curve 1105 over the 16×16 pixel grid of the reconstructed raster representation. The Hilbert curve 1105 enables the compression module 303 to reconstruct the index place order of each bin or pixel in the reconstructed raster representation 1103. The compression module 1103 can then fill in the bins (e.g., indicated by gray shading) corresponding to the index values of the data-containing bins in the compressed data structure 1101. All other bins or pixels of the reconstructed raster image 1103 can remain empty (e.g., indicated by white coloring of the respective bins) to complete the reconstruction of the original image or raster representation. In this way, the spatial relationships and locality of the bins/pixels can be accurately reconstructed.

In step 905, the output module 307 can provide the spatial relationship data as an output. In one embodiment, the spatial relationship data can be provided indirectly as part of the output of the ML task (e.g., inference data 107). If the ML task is used to process the compressed data 119 for ML-based traffic prediction, routing, POI recommendation, etc., then the inference data 107 itself can be output for presentation on a user device (e.g., UE 129 and/or vehicle 133).

In embodiments in which the original data or image is reconstructed from the data, the output can be the reconstructed original data, image, raster representation, etc. The original image can then be displayed, presented, or otherwise used by an end user device (e.g., UE 129 and/or vehicle 133).

Returning to FIG. 1, as shown, the system 100 includes a machine learning system 105 for providing a generalizable semantic-aware location representation for machine learning tasks such as entity matching for combining data sources and/or relationship prediction. In one embodiment, the machine learning system 105 includes or is otherwise associated with one or more machine learning models 103 (e.g., neural networks or other equivalent network) for performing location-based ML tasks relying on the compressed data 119 generated according to the embodiments described herein. The machine learning models 103 can also be used as part of a computer vision system for detecting new or updated mapping features through image analysis.

In one embodiment, the machine learning system 105 has connectivity over the communication network 121 to the mapping platform 117, services platform 123 that provides one or more services 125 that can use compressed data 119 for downstream machine learning tasks to perform one or more functions. By way of example, the services 125 may be third party services and include but is not limited to mapping services, navigation services, travel planning services, notification services, social networking services, content (e.g., audio, video, images, etc.) provisioning services, application services, storage services, contextual information determination services, location-based services, information-based services (e.g., weather, news, etc.), etc. In one embodiment, the services 125 uses the output of the mapping platform 117 (e.g., compressed data 119) and/or machine learning system 105 (e.g., inference data 107) to provide services 125 such as navigation, mapping, other location-based services, etc. to the vehicles 133, UEs 129, and/or applications 131 executing on the UEs 129.

In one embodiment, the machine learning system 105 may be a platform with multiple interconnected components. The machine learning system 105 may include multiple servers, intelligent networking devices, computing devices, components, and corresponding software for combining location data sources according to the various embodiments described herein. In addition, it is noted that the machine learning system 105 may be a separate entity of the system 100, a part of the mapping platform 117, one or more services 125, a part of the services platform 123, or included within components of the vehicles 133 and/or UEs 129.

In one embodiment, content providers 127 may provide content or data (e.g., including geographic data, etc.) to the geographic database 111, machine learning system 105, the mapping platform 117, the services platform 123, the services 125, the vehicles 133, the UEs 129, and/or the applications 131 executing on the UEs 129. The content provided may be any type of content, such as machine learning models, map embeddings, map content, textual content, audio content, video content, image content, etc. In one embodiment, the content providers 127 may provide content that may aid in compressing data according to the various embodiments described herein. In one embodiment, the content providers 127 may also store content associated with the machine learning system 105, geographic database 111, mapping platform 117, services platform 123, services 125, and/or any other component of the system 100. In another embodiment, the content providers 127 may manage access to a central repository of data, and offer a consistent, standard interface to data, such as a repository of the geographic database 111.

In one embodiment, the vehicles 133 and/or UEs 129 may execute software applications 131 to used compressed data 119 and/or inference data 107 according to the embodiments described herein. By way of example, the applications 131 may also be any type of application that is executable on the vehicles 133 and/or UEs 129, such as autonomous driving applications, mapping applications, location-based service applications, navigation applications, device control applications, content provisioning services, camera/imaging application, media player applications, social networking applications, calendar applications, and the like. In one embodiment, the applications 131 may act as a client for the mapping platform 117 and perform one or more functions associated with compressing data for machine learning or equivalent tasks alone or in combination with the mapping platform 117.

By way of example, the vehicles 133 and/or UEs 129 is or can include any type of embedded system, mobile terminal, fixed terminal, or portable terminal including a built-in navigation system, a personal navigation device, mobile handset, station, unit, device, multimedia computer, multimedia tablet, Internet node, communicator, desktop computer, laptop computer, notebook computer, netbook computer, tablet computer, personal communication system (PCS) device, personal digital assistants (PDAs), audio/video player, digital camera/camcorder, positioning device, fitness device, television receiver, radio broadcast receiver, electronic book device, game device, or any combination thereof, including the accessories and peripherals of these devices, or any combination thereof. It is also contemplated that the vehicles 133 and/or UEs 129 can support any type of interface to the user (such as “wearable” circuitry, etc.). In one embodiment, the vehicles 133 and/or UEs 129 may be associated with or be a component of a vehicle or any other device.

In one embodiment, the vehicles 133 and/or UEs 129 are configured with various sensors for generating or collecting environmental image data, related geographic data, etc. In one embodiment, the sensed data represent sensor data associated with a geographic location or coordinates at which the sensor data was collected, and the polyline or polygonal representations of detected objects of interest derived therefrom to generate the digital map data of the geographic database 111. By way of example, the sensors may include a global positioning sensor for gathering location data (e.g., GPS), IMUs, a network detection sensor for detecting wireless signals or receivers for different short-range communications (e.g., Bluetooth, Wi-Fi, Li-Fi, near field communication (NFC) etc.), temporal information sensors, a camera/imaging sensor for gathering image data (e.g., the camera sensors may automatically capture road sign information, images of road obstructions, etc. for analysis), an audio recorder for gathering audio data, velocity sensors mounted on steering wheels of the vehicles, switch sensors for determining whether one or more vehicle switches are engaged, and the like.

Other examples of sensors of the vehicles 133 and/or UEs 129 may include light sensors, orientation sensors augmented with height sensors and acceleration sensor, tilt sensors to detect the degree of incline or decline (e.g., slope) along a path of travel, moisture sensors, pressure sensors, etc. In a further example embodiment, sensors about the perimeter of the vehicles 133 and/or UEs 129 may detect the relative distance of the device or vehicle from a lane or roadway, the presence of other vehicles, pedestrians, traffic lights, potholes and any other objects, or a combination thereof. In one scenario, the sensors may detect weather data, traffic information, or a combination thereof. In one embodiment, the vehicles 133 and/or UEs 129 may include GPS or other satellite-based receivers to obtain geographic coordinates from positioning satellites for determining current location and time. Further, the location can be determined by visual odometry, triangulation systems such as A-GPS, Cell of Origin, or other location extrapolation technologies.

In one embodiment, the communication network 121 of system 100 includes one or more networks such as a data network, a wireless network, a telephony network, or any combination thereof. It is contemplated that the data network may be any local area network (LAN), metropolitan area network (MAN), wide area network (WAN), a public data network (e.g., the Internet), short range wireless network, or any other suitable packet-switched network, such as a commercially owned, proprietary packet-switched network, e.g., a proprietary cable or fiber-optic network, and the like, or any combination thereof. In addition, the wireless network may be, for example, a cellular network and may employ various technologies including enhanced data rates for global evolution (EDGE), general packet radio service (GPRS), global system for mobile communications (GSM), Internet protocol multimedia subsystem (IMS), universal mobile telecommunications system (UNITS), etc., as well as any other suitable wireless medium, e.g., worldwide interoperability for microwave access (WiMAX), Long Term Evolution (LTE) networks, 5G New Radio networks, code division multiple access (CDMA), wideband code division multiple access (WCDMA), wireless fidelity (Wi-Fi), wireless LAN (WLAN), Bluetooth®, Internet Protocol (IP) data casting, satellite, mobile ad-hoc network (MANET), and the like, or any combination thereof.

By way of example, the machine learning system 105, mapping platform 117, services platform 123, services 125, vehicles 133 and/or UEs 129, and/or content providers 127 communicate with each other and other components of the system 100 using well known, new or still developing protocols. In this context, a protocol includes a set of rules defining how the network nodes within the communication network 121 interact with each other based on information sent over the communication links. The protocols are effective at different layers of operation within each node, from generating and receiving physical signals of various types, to selecting a link for transferring those signals, to the format of information indicated by those signals, to identifying which software application executing on a computer system sends or receives the information. The conceptually different layers of protocols for exchanging information over a network are described in the Open Systems Interconnection (OSI) Reference Model.

Communications between the network nodes are typically effected by exchanging discrete packets of data. Each packet typically comprises (1) header information associated with a particular protocol, and (2) payload information that follows the header information and contains information that may be processed independently of that particular protocol. In some protocols, the packet includes (3) trailer information following the payload and indicating the end of the payload information. The header includes information such as the source of the packet, its destination, the length of the payload, and other properties used by the protocol. Often, the data in the payload for the particular protocol includes a header and payload for a different protocol associated with a different, higher layer of the OSI Reference Model. The header for a particular protocol typically indicates a type for the next protocol contained in its payload. The higher layer protocol is said to be encapsulated in the lower layer protocol. The headers included in a packet traversing multiple heterogeneous networks, such as the Internet, typically include a physical (layer 1) header, a data-link (layer 2) header, an internetwork (layer 3) header and a transport (layer 4) header, and various application (layer 5, layer 6 and layer 7) headers as defined by the OSI Reference Model.

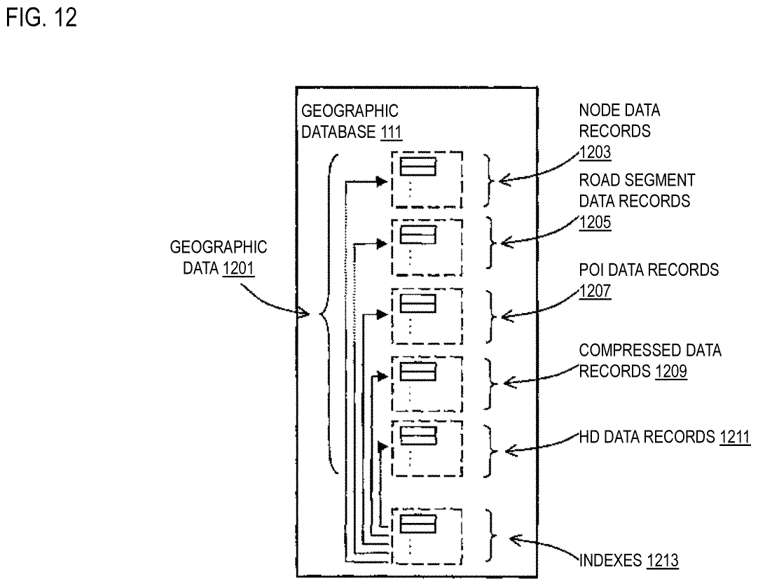

FIG. 12 is a diagram of a geographic database 111, according to one embodiment. In one embodiment, the geographic database 111 includes geographic data 1201 used for (or configured to be compiled to be used for) mapping and/or navigation-related services, such as for providing map embedding analytics according to the embodiments described herein. For example, the map data records stored herein can be used to determine the semantic relationships among the map features, attributes, categories, etc. represented in the geographic data 1201. In one embodiment, the geographic database 111 include high definition (HD) mapping data that provide centimeter-level or better accuracy of map features. For example, the geographic database 111 can be based on Light Detection and Ranging (LiDAR) or equivalent technology to collect billions of 3D points and model road surfaces and other map features down to the number lanes and their widths. In one embodiment, the HD mapping data (e.g., HD data records 1211) capture and store details such as the slope and curvature of the road, lane markings, roadside objects such as signposts, including what the signage denotes. By way of example, the HD mapping data enable highly automated vehicles to precisely localize themselves on the road.

In one embodiment, geographic features (e.g., two-dimensional or three-dimensional features) are represented using polylines and/or polygons (e.g., two-dimensional features) or polygon extrusions (e.g., three-dimensional features). In one embodiment, these polylines/polygons can also represent ground truth or reference features or objects (e.g., signs, road markings, lane lines, landmarks, etc.) used for visual odometry. For example, the polylines or polygons can correspond to the boundaries or edges of the respective geographic features. In the case of a building, a two-dimensional polygon can be used to represent a footprint of the building, and a three-dimensional polygon extrusion can be used to represent the three-dimensional surfaces of the building. Accordingly, the terms polygons and polygon extrusions as used herein can be used interchangeably.

In one embodiment, the following terminology applies to the representation of geographic features in the geographic database 111.

“Node”—A point that terminates a link.

“Line segment”—A straight line connecting two points.

“Link” (or “edge”)—A contiguous, non-branching string of one or more line segments terminating in a node at each end.

“Shape point”—A point along a link between two nodes (e.g., used to alter a shape of the link without defining new nodes).

“Oriented link”—A link that has a starting node (referred to as the “reference node”) and an ending node (referred to as the “non reference node”).

“Simple polygon”—An interior area of an outer boundary formed by a string of oriented links that begins and ends in one node. In one embodiment, a simple polygon does not cross itself.

“Polygon”—An area bounded by an outer boundary and none or at least one interior boundary (e.g., a hole or island). In one embodiment, a polygon is constructed from one outer simple polygon and none or at least one inner simple polygon. A polygon is simple if it just consists of one simple polygon, or complex if it has at least one inner simple polygon.

In one embodiment, the geographic database 111 follows certain conventions. For example, links do not cross themselves and do not cross each other except at a node. Also, there are no duplicated shape points, nodes, or links. Two links that connect each other have a common node. In the geographic database 111, overlapping geographic features are represented by overlapping polygons. When polygons overlap, the boundary of one polygon crosses the boundary of the other polygon. In the geographic database 111, the location at which the boundary of one polygon intersects they boundary of another polygon is represented by a node. In one embodiment, a node may be used to represent other locations along the boundary of a polygon than a location at which the boundary of the polygon intersects the boundary of another polygon. In one embodiment, a shape point is not used to represent a point at which the boundary of a polygon intersects the boundary of another polygon.

As shown, the geographic database 111 includes node data records 1203, road segment or link data records 1205, POI data records 1207, compressed data records 1209, HD mapping data records 1211, and indexes 1213, for example. More, fewer, or different data records can be provided. In one embodiment, additional data records (not shown) can include cartographic (“carto”) data records, routing data, and maneuver data. In one embodiment, the indexes 1213 may improve the speed of data retrieval operations in the geographic database 111. In one embodiment, the indexes 1213 may be used to quickly locate data without having to search every row in the geographic database 111 every time it is accessed. For example, in one embodiment, the indexes 1213 can be a spatial index of the polygon points associated with stored feature polygons.

In exemplary embodiments, the road segment data records 1205 are links or segments representing roads, streets, or paths, as can be used in the calculated route or recorded route information for determination of one or more personalized routes. The node data records 1203 are end points (for example, representing intersections or an end of a road) corresponding to the respective links or segments of the road segment data records 1205. The road link data records 1205 and the node data records 1203 represent a road network, such as used by vehicles, cars, and/or other entities. Alternatively, the geographic database 111 can contain path segment and node data records or other data that represent pedestrian paths or areas in addition to or instead of the vehicle road record data, for example.

The road/link segments and nodes can be associated with attributes, such as geographic coordinates, street names, address ranges, speed limits, turn restrictions at intersections, and other navigation related attributes, as well as POIs, such as gasoline stations, hotels, restaurants, museums, stadiums, offices, automobile dealerships, auto repair shops, buildings, stores, parks, etc. The geographic database 111 can include data about the POIs and their respective locations in the POI data records 1207. The geographic database 111 can also include data about places, such as cities, towns, or other communities, and other geographic features, such as bodies of water, mountain ranges, etc. Such place or feature data can be part of the POI data records 1207 or can be associated with POIs or POI data records 1207 (such as a data point used for displaying or representing a position of a city).

In one embodiment, the geographic database 111 can also include compressed data records 1209 for storing compressed data 119, space filling curve characteristics, raster representations, and/or any other related data that is used or generated according to the embodiments described herein. By way of example, the compressed data records 1209 can be associated with one or more of the node records 1203, road segment records 1205, and/or POI data records 1207 to associate the compressed data 119 with specific places, POIs, geographic areas, and/or other map features. In this way, the compressed data records 1209 can also be associated with the characteristics or metadata of the corresponding records 1203, 1205, and/or 1207.

In one embodiment, as discussed above, the HD mapping data records 1211 model road surfaces and other map features to centimeter-level or better accuracy. The HD mapping data records 1211 also include ground truth object models that provide the precise object geometry with polylines or polygonal boundaries, as well as rich attributes of the models. These rich attributes include, but are not limited to, object type, object location, lane traversal information, lane types, lane marking types, lane level speed limit information, and/or the like. In one embodiment, the HD mapping data records 1211 are divided into spatial partitions of varying sizes to provide HD mapping data to end user devices with near real-time speed without overloading the available resources of the devices (e.g., computational, memory, bandwidth, etc. resources).

In one embodiment, the HD mapping data records 1211 are created from high-resolution 3D mesh or point-cloud data generated, for instance, from LiDAR-equipped vehicles. The 3D mesh or point-cloud data are processed to create 3D representations of a street or geographic environment at centimeter-level accuracy for storage in the HD mapping data records 1211.

In one embodiment, the HD mapping data records 1211 also include real-time sensor data collected from probe vehicles in the field. The real-time sensor data, for instance, integrates real-time traffic information, weather, and road conditions (e.g., potholes, road friction, road wear, etc.) with highly detailed 3D representations of street and geographic features to provide precise real-time data (e.g., including probe trajectories) also at centimeter-level accuracy. Other sensor data can include vehicle telemetry or operational data such as windshield wiper activation state, braking state, steering angle, accelerator position, and/or the like.

In one embodiment, the geographic database 111 can be maintained by the content provider 127 in association with the services platform 123 (e.g., a map developer). The map developer can collect geographic data to generate and enhance the geographic database 111. There can be different ways used by the map developer to collect data. These ways can include obtaining data from other sources, such as municipalities or respective geographic authorities. In addition, the map developer can employ field personnel to travel by vehicle along roads throughout the geographic region to observe features and/or record information about them, for example. Also, remote sensing, such as aerial or satellite photography, can be used.

The geographic database 111 can be a master geographic database stored in a format that facilitates updating, maintenance, and development. For example, the master geographic database or data in the master geographic database can be in an Oracle spatial format or other format (e.g., capable of accommodating multiple/different map layers), such as for development or production purposes. The Oracle spatial format or development/production database can be compiled into a delivery format, such as a geographic data files (GDF) format. The data in the production and/or delivery formats can be compiled or further compiled to form geographic database products or databases, which can be used in end user navigation devices or systems.

For example, geographic data is compiled (such as into a platform specification format (PSF)) to organize and/or configure the data for performing navigation-related functions and/or services, such as route calculation, route guidance, map display, speed calculation, distance and travel time functions, and other functions, by a navigation device, such as by vehicles 133 and/or UEs 129. The navigation-related functions can correspond to vehicle navigation, pedestrian navigation, or other types of navigation. The compilation to produce the end user databases can be performed by a party or entity separate from the map developer. For example, a customer of the map developer, such as a navigation device developer or other end user device developer, can perform compilation on a received geographic database in a delivery format to produce one or more compiled navigation databases.

The processes described herein for compression of sparse data for machine learning or equivalent tasks may be advantageously implemented via software, hardware (e.g., general processor, Digital Signal Processing (DSP) chip, an Application Specific Integrated Circuit (ASIC), Field Programmable Gate Arrays (FPGAs), etc.), firmware or a combination thereof. Such exemplary hardware for performing the described functions is detailed below.

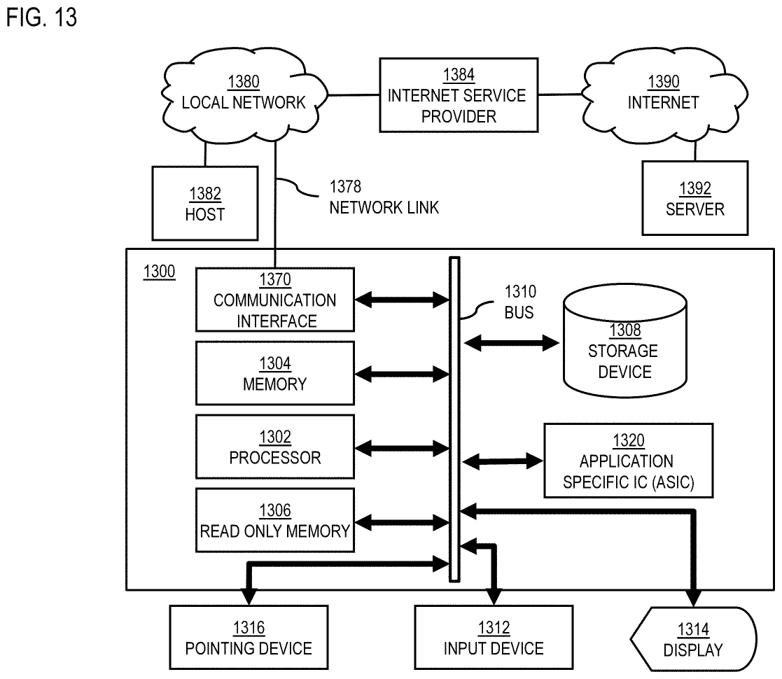

FIG. 13 illustrates a computer system 1300 upon which an embodiment of the invention may be implemented. Computer system 1300 is programmed (e.g., via computer program code or instructions) to combine location data sources as described herein and includes a communication mechanism such as a bus 1310 for passing information between other internal and external components of the computer system 1300. Information (also called data) is represented as a physical expression of a measurable phenomenon, typically electric voltages, but including, in other embodiments, such phenomena as magnetic, electromagnetic, pressure, chemical, biological, molecular, atomic, sub-atomic and quantum interactions. For example, north and south magnetic fields, or a zero and non-zero electric voltage, represent two states (0, 1) of a binary digit (bit). Other phenomena can represent digits of a higher base. A superposition of multiple simultaneous quantum states before measurement represents a quantum bit (qubit). A sequence of one or more digits constitutes digital data that is used to represent a number or code for a character. In some embodiments, information called analog data is represented by a near continuum of measurable values within a particular range.

A bus 1310 includes one or more parallel conductors of information so that information is transferred quickly among devices coupled to the bus 1310. One or more processors 1302 for processing information are coupled with the bus 1310.

A processor 1302 performs a set of operations on information as specified by computer program code related to combining location data sources. The computer program code is a set of instructions or statements providing instructions for the operation of the processor and/or the computer system to perform specified functions. The code, for example, may be written in a computer programming language that is compiled into a native instruction set of the processor. The code may also be written directly using the native instruction set (e.g., machine language). The set of operations include bringing information in from the bus 1310 and placing information on the bus 1310. The set of operations also typically include comparing two or more units of information, shifting positions of units of information, and combining two or more units of information, such as by addition or multiplication or logical operations like OR, exclusive OR (XOR), and AND. Each operation of the set of operations that can be performed by the processor is represented to the processor by information called instructions, such as an operation code of one or more digits. A sequence of operations to be executed by the processor 1302, such as a sequence of operation codes, constitute processor instructions, also called computer system instructions or, simply, computer instructions. Processors may be implemented as mechanical, electrical, magnetic, optical, chemical or quantum components, among others, alone or in combination.

Computer system 1300 also includes a memory 1304 coupled to bus 1310. The memory 1304, such as a random access memory (RANI) or other dynamic storage device, stores information including processor instructions for combining location data sources. Dynamic memory allows information stored therein to be changed by the computer system 1300. RAM allows a unit of information stored at a location called a memory address to be stored and retrieved independently of information at neighboring addresses. The memory 1304 is also used by the processor 1302 to store temporary values during execution of processor instructions. The computer system 1300 also includes a read only memory (ROM) 1306 or other static storage device coupled to the bus 1310 for storing static information, including instructions, that is not changed by the computer system 1300. Some memory is composed of volatile storage that loses the information stored thereon when power is lost. Also coupled to bus 1310 is a non-volatile (persistent) storage device 1308, such as a magnetic disk, optical disk, or flash card, for storing information, including instructions, that persists even when the computer system 1300 is turned off or otherwise loses power.

Information, including instructions for combining location data sources, is provided to the bus 1310 for use by the processor from an external input device 1312, such as a keyboard containing alphanumeric keys operated by a human user, or a sensor. A sensor detects conditions in its vicinity and transforms those detections into physical expression compatible with the measurable phenomenon used to represent information in computer system 1300. Other external devices coupled to bus 1310, used primarily for interacting with humans, include a display device 1314, such as a cathode ray tube (CRT) or a liquid crystal display (LCD), or plasma screen or printer for presenting text or images, and a pointing device 1316, such as a mouse or a trackball or cursor direction keys, or motion sensor, for controlling a position of a small cursor image presented on the display 1314 and issuing commands associated with graphical elements presented on the display 1314. In some embodiments, for example, in embodiments in which the computer system 1300 performs all functions automatically without human input, one or more of external input device 1312, display device 1314 and pointing device 1316 is omitted.

In the illustrated embodiment, special purpose hardware, such as an application specific integrated circuit (ASIC) 1320, is coupled to bus 1310. The special purpose hardware is configured to perform operations not performed by processor 1302 quickly enough for special purposes. Examples of application specific ICs include graphics accelerator cards for generating images for display 1314, cryptographic boards for encrypting and decrypting messages sent over a network, speech recognition, and interfaces to special external devices, such as robotic arms and medical scanning equipment that repeatedly perform some complex sequence of operations that are more efficiently implemented in hardware.

Computer system 1300 also includes one or more instances of a communications interface 1370 coupled to bus 1310. Communication interface 1370 provides a one-way or two-way communication coupling to a variety of external devices that operate with their own processors, such as printers, scanners, and external disks. In general, the coupling is with a network link 1378 that is connected to a local network 1380 to which a variety of external devices with their own processors are connected. For example, communication interface 1370 may be a parallel port or a serial port or a universal serial bus (USB) port on a personal computer. In some embodiments, communications interface 1370 is an integrated services digital network (ISDN) card or a digital subscriber line (DSL) card or a telephone modem that provides an information communication connection to a corresponding type of telephone line. In some embodiments, a communication interface 1370 is a cable modem that converts signals on bus 1310 into signals for a communication connection over a coaxial cable or into optical signals for a communication connection over a fiber optic cable. As another example, communications interface 1370 may be a local area network (LAN) card to provide a data communication connection to a compatible LAN, such as Ethernet. Wireless links may also be implemented. For wireless links, the communications interface 1370 sends or receives or both sends and receives electrical, acoustic, or electromagnetic signals, including infrared and optical signals, that carry information streams, such as digital data. For example, in wireless handheld devices, such as mobile telephones like cell phones, the communications interface 1370 includes a radio band electromagnetic transmitter and receiver called a radio transceiver. In certain embodiments, the communications interface 1370 enables connection to the communication network 121 for combining location data sources.

The term computer-readable medium is used herein to refer to any medium that participates in providing information to processor 1302, including instructions for execution. Such a medium may take many forms, including, but not limited to, non-volatile media, volatile media, and transmission media. Non-volatile media include, for example, optical or magnetic disks, such as storage device 1308. Volatile media include, for example, dynamic memory 1304. Transmission media include, for example, coaxial cables, copper wire, fiber optic cables, and carrier waves that travel through space without wires or cables, such as acoustic waves and electromagnetic waves, including radio, optical and infrared waves. Signals include man-made transient variations in amplitude, frequency, phase, polarization, or other physical properties transmitted through the transmission media. Common forms of computer-readable media include, for example, a floppy disk, a flexible disk, hard disk, magnetic tape, any other magnetic medium, a CD-ROM, CDRW, DVD, any other optical medium, punch cards, paper tape, optical mark sheets, any other physical medium with patterns of holes or other optically recognizable indicia, a RAM, a PROM, an EPROM, a FLASH-EPROM, any other memory chip or cartridge, a carrier wave, or any other medium from which a computer can read.

Network link 1378 typically provides information communication using transmission media through one or more networks to other devices that use or process the information. For example, network link 1378 may provide a connection through local network 1380 to a host computer 1382 or to equipment 1384 operated by an Internet Service Provider (ISP). ISP equipment 1384 in turn provides data communication services through the public, world-wide packet-switching communication network of networks now commonly referred to as the Internet 1390.

A computer called a server host 1392 connected to the Internet hosts a process that provides a service in response to information received over the Internet. For example, server host 1392 hosts a process that provides information representing video data for presentation at display 1314. It is contemplated that the components of system can be deployed in various configurations within other computer systems, e.g., host 1382 and server 1392.

FIG. 14 illustrates a chip set 1400 upon which an embodiment of the invention may be implemented. Chip set 1400 is programmed to combine location data sources as described herein and includes, for instance, the processor and memory components described with respect to FIG. 13 incorporated in one or more physical packages (e.g., chips). By way of example, a physical package includes an arrangement of one or more materials, components, and/or wires on a structural assembly (e.g., a baseboard) to provide one or more characteristics such as physical strength, conservation of size, and/or limitation of electrical interaction. It is contemplated that in certain embodiments the chip set can be implemented in a single chip.

In one embodiment, the chip set 1400 includes a communication mechanism such as a bus 1401 for passing information among the components of the chip set 1400. A processor 1403 has connectivity to the bus 1401 to execute instructions and process information stored in, for example, a memory 1405. The processor 1403 may include one or more processing cores with each core configured to perform independently. A multi-core processor enables multiprocessing within a single physical package. Examples of a multi-core processor include two, four, eight, or greater numbers of processing cores. Alternatively or in addition, the processor 1403 may include one or more microprocessors configured in tandem via the bus 1401 to enable independent execution of instructions, pipelining, and multithreading. The processor 1403 may also be accompanied with one or more specialized components to perform certain processing functions and tasks such as one or more digital signal processors (DSP) 1407, or one or more application-specific integrated circuits (ASIC) 1409. A DSP 1407 typically is configured to process real-world signals (e.g., sound) in real time independently of the processor 1403. Similarly, an ASIC 1409 can be configured to performed specialized functions not easily performed by a general purposed processor. Other specialized components to aid in performing the inventive functions described herein include one or more field programmable gate arrays (FPGA) (not shown), one or more controllers (not shown), or one or more other special-purpose computer chips.

The processor 1403 and accompanying components have connectivity to the memory 1405 via the bus 1401. The memory 1405 includes both dynamic memory (e.g., RAM, magnetic disk, writable optical disk, etc.) and static memory (e.g., ROM, CD-ROM, etc.) for storing executable instructions that when executed perform the inventive steps described herein to combine location data sources. The memory 1405 also stores the data associated with or generated by the execution of the inventive steps.

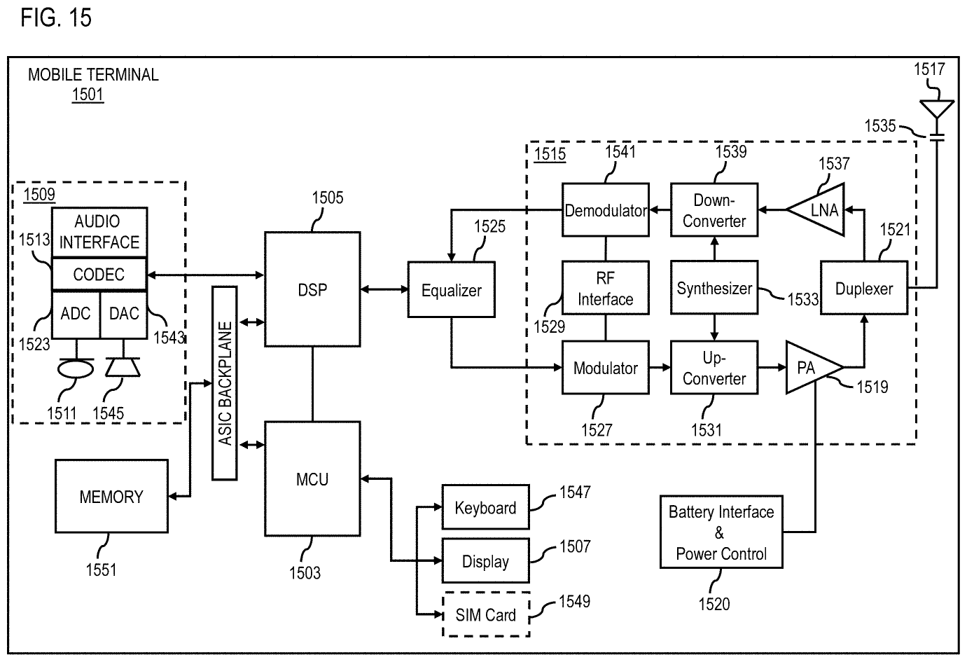

FIG. 15 is a diagram of exemplary components of a mobile terminal 1501 (e.g., a vehicle 133 and/or UE 129 or component thereof) capable of operating in the system of FIG. 1, according to one embodiment. Generally, a radio receiver is often defined in terms of front-end and back-end characteristics. The front-end of the receiver encompasses all of the Radio Frequency (RF) circuitry whereas the back-end encompasses all of the base-band processing circuitry. Pertinent internal components of the telephone include a Main Control Unit (MCU) 1503, a Digital Signal Processor (DSP) 1505, and a receiver/transmitter unit including a microphone gain control unit and a speaker gain control unit. A main display unit 1507 provides a display to the user in support of various applications and mobile station functions that offer automatic contact matching. An audio function circuitry 1509 includes a microphone 1511 and microphone amplifier that amplifies the speech signal output from the microphone 1511. The amplified speech signal output from the microphone 1511 is fed to a coder/decoder (CODEC) 1513.

A radio section 1515 amplifies power and converts frequency in order to communicate with a base station, which is included in a mobile communication system, via antenna 1517. The power amplifier (PA) 1519 and the transmitter/modulation circuitry are operationally responsive to the MCU 1503, with an output from the PA 1519 coupled to the duplexer 1521 or circulator or antenna switch, as known in the art. The PA 1519 also couples to a battery interface and power control unit 1520.

In use, a user of mobile station 1501 speaks into the microphone 1511 and his or her voice along with any detected background noise is converted into an analog voltage. The analog voltage is then converted into a digital signal through the Analog to Digital Converter (ADC) 1523. The control unit 1503 routes the digital signal into the DSP 1505 for processing therein, such as speech encoding, channel encoding, encrypting, and interleaving. In one embodiment, the processed voice signals are encoded, by units not separately shown, using a cellular transmission protocol such as global evolution (EDGE), general packet radio service (GPRS), global system for mobile communications (GSM), Internet protocol multimedia subsystem (IMS), universal mobile telecommunications system (UNITS), etc., as well as any other suitable wireless medium, e.g., microwave access (WiMAX), Long Term Evolution (LTE) networks, 5G New Radio networks, code division multiple access (CDMA), wireless fidelity (WiFi), satellite, and the like.

The encoded signals are then routed to an equalizer 1525 for compensation of any frequency-dependent impairments that occur during transmission though the air such as phase and amplitude distortion. After equalizing the bit stream, the modulator 1527 combines the signal with a RF signal generated in the RF interface 1529. The modulator 1527 generates a sine wave by way of frequency or phase modulation. In order to prepare the signal for transmission, an up-converter 1531 combines the sine wave output from the modulator 1527 with another sine wave generated by a synthesizer 1533 to achieve the desired frequency of transmission. The signal is then sent through a PA 1519 to increase the signal to an appropriate power level. In practical systems, the PA 1519 acts as a variable gain amplifier whose gain is controlled by the DSP 1505 from information received from a network base station. The signal is then filtered within the duplexer 1521 and optionally sent to an antenna coupler 1535 to match impedances to provide maximum power transfer. Finally, the signal is transmitted via antenna 1517 to a local base station. An automatic gain control (AGC) can be supplied to control the gain of the final stages of the receiver. The signals may be forwarded from there to a remote telephone which may be another cellular telephone, other mobile phone or a land-line connected to a Public Switched Telephone Network (PSTN), or other telephony networks.

Voice signals transmitted to the mobile station 1501 are received via antenna 1517 and immediately amplified by a low noise amplifier (LNA) 1537. A down-converter 1539 lowers the carrier frequency while the demodulator 1541 strips away the RF leaving only a digital bit stream. The signal then goes through the equalizer 1525 and is processed by the DSP 1505. A Digital to Analog Converter (DAC) 1543 converts the signal and the resulting output is transmitted to the user through the speaker 1545, all under control of a Main Control Unit (MCU) 1503—which can be implemented as a Central Processing Unit (CPU) (not shown).

The MCU 1503 receives various signals including input signals from the keyboard 1547. The keyboard 1547 and/or the MCU 1503 in combination with other user input components (e.g., the microphone 1511) comprise a user interface circuitry for managing user input. The MCU 1503 runs a user interface software to facilitate user control of at least some functions of the mobile station 1501 to combine location data sources. The MCU 1503 also delivers a display command and a switch command to the display 1507 and to the speech output switching controller, respectively. Further, the MCU 1503 exchanges information with the DSP 1505 and can access an optionally incorporated SIM card 1549 and a memory 1551. In addition, the MCU 1503 executes various control functions required of the station. The DSP 1505 may, depending upon the implementation, perform any of a variety of conventional digital processing functions on the voice signals. Additionally, DSP 1505 determines the background noise level of the local environment from the signals detected by microphone 1511 and sets the gain of microphone 1511 to a level selected to compensate for the natural tendency of the user of the mobile station 1501.

The CODEC 1513 includes the ADC 1523 and DAC 1543. The memory 1551 stores various data including call incoming tone data and is capable of storing other data including music data received via, e.g., the global Internet. The software module could reside in RAM memory, flash memory, registers, or any other form of writable computer-readable storage medium known in the art including non-transitory computer-readable storage medium. For example, the memory device 1551 may be, but not limited to, a single memory, CD, DVD, ROM, RAM, EEPROM, optical storage, or any other non-volatile or non-transitory storage medium capable of storing digital data.

An optionally incorporated SIM card 1549 carries, for instance, important information, such as the cellular phone number, the carrier supplying service, subscription details, and security information. The SIM card 1549 serves primarily to identify the mobile station 1501 on a radio network. The card 1549 also contains a memory for storing a personal telephone number registry, text messages, and user specific mobile station settings.

While the invention has been described in connection with a number of embodiments and implementations, the invention is not so limited but covers various obvious modifications and equivalent arrangements, which fall within the purview of the appended claims. Although features of the invention are expressed in certain combinations among the claims, it is contemplated that these features can be arranged in any combination and order.

What is claimed is:

1. A computer-implemented method comprising:
receiving data that is binned into a plurality of bins, wherein the data represents a spatial surface;
processing the data by applying a compression criterion to classify one or more bins of the plurality of bins as either data-containing bins or empty bins;
establishing a space filling curve over the plurality of bins, wherein the space filling curve linearizes the plurality of bins according to a placement order;
storing the data-containing bins of the plurality of bins in a compressed data structure based on the placement order of the space filling curve; and
providing the compressed data structure as an output.

2. The method of claim 1, wherein the compressed data structure is indexed based on a tree structure comprising one or more spatial clusters of the plurality of bins.

3. The method of claim 2, wherein the compressed data comprises a header and one or more data frames; wherein the header stores one or more characteristics of the space filling curve, the tree structure, or a combination thereof; and wherein the one or more data frames store the data associated with the data-containing bins.

4. The method of claim 1, wherein the space filling curve comprises one or more curve levels respectively corresponding to one or more tree levels of the tree structure.

5. The method of claim 1, wherein the compressed data structure is a single dimensional array.

6. The method of claim 1, wherein the compressed data structure is a dense multidimensional data structure.

7. The method of claim 1, wherein the plurality of bins is respectively associated with coordinate data of a coordinate system, and wherein the space filling curve converts the coordinate data to and from the coordinate system and the placement order of the space filing curve.

8. The method of claim 1, wherein the output is provided as an input into a machine learning model.

9. The method of claim 1, wherein the spatial surface corresponds to a geographic region.

10. The method of claim 1, wherein the data comprises a plurality of data layers, and wherein the plurality of multiple data layers of the data in the data-containing bins is stored in the compressed data structure based on the placement order of the space filling curve.

11. The method of claim 10, wherein the plurality of data layers include a road network layer representing one or more roads associated with the spatial surface, a traffic data layer representing traffic associated with the spatial surface, an accident data layer representing one or more accidents associated with the spatial surface, or a combination thereof; and wherein the compression criterion classifies the one or more bins based on a distance threshold between the one or more roads and either of the traffic or the one or more accidents. t

12. The method of claim 1, wherein the data is stored in a matrix, and wherein the plurality of bins corresponds to one or more elements of the matrix.

13. An apparatus comprising:
at least one processor; and
at least one memory including computer program code for one or more programs,
the at least one memory and the computer program code configured to, within the at least one processor, cause the apparatus to perform at least the following,
receive a compressed data structure representing binned data, wherein the binned data has been processed by applying a compression criterion to classify the plurality of bins of the binned data as either data-containing bins or empty bins, and wherein the compressed data structure stores the data-containing bins linearized according to a placement order of a space-filling curve;
extract spatial relationship data of the binned data based on the placement order of the data-containing bins determined from the space filling curve; and
provide the spatial relationship data as an output.

14. The apparatus of claim 13, wherein the spatial relationship data is extracted by providing the output as an input into a machine learning model.

15. The apparatus of claim 13, wherein the compressed data structure is indexed based on a tree structure comprising one or more spatial clusters of the plurality of bins.

16. The apparatus of claim 15, wherein the compressed data comprises a header and one or more data frames; wherein the header stores one or more characteristics of the space filling curve, the tree structure, or a combination thereof; and wherein the one or more data frames store the data associated with the data-containing bins.

17. A non-transitory computer-readable storage medium carrying one or more sequences of one or more instructions which, when executed by one or more processors, cause an apparatus to perform:
processing a sparse matrix by applying a compression criterion to classify one or more elements of the sparse matrix as either data-containing elements or empty elements;
establishing a space filling curve over the plurality of elements, wherein the space filling curve linearizes the plurality of elements according to a placement order;
storing the data-containing bins of the plurality of bins in a compressed data structure based on the placement order; and
providing the compressed data structure as an output.

18. The non-transitory computer-readable storage medium of claim 17, wherein the compressed data structure is indexed based on a tree structure comprising one or more spatial clusters of the plurality of bins.

19. The non-transitory computer-readable storage medium of claim 18, wherein the compressed data comprises a header and one or more data frames; wherein the header stores one or more characteristics of the space filling curve, the tree structure, or a combination thereof; and wherein the one or more data frames store data associated with the data-containing bins.

20. The non-transitory computer-readable storage medium of claim 17, wherein the space filling curve comprises one or more curve levels respectively corresponding to one or more tree levels of the tree structure.
